(19) United States
(12) Patent Application Publication
(10) Pub. No.: US 2025/0279784 A1
(43) Pub. Date: Sep. 4, 2025

(54) DIGITAL-TO-ANALOG CONVERTER

(71) Applicant: Analog Devices International Unlimited Company, Co. Limerick (IE)

(72) Inventors: Roderick MCLACHLAN, Dalgety Bay (GB); Ken Bryan FABAY, Binangonan (PH); Sharad VIJAYKUMAR, Mysore (IN); Dennis A Dempsey, Newport (IE)

(21) Appl. No.: 19/210,379

(22) Filed: May 16, 2025

Related U.S. Application Data
(63) Continuation-in-part of application No. 18/679,005, filed on May 30, 2024.
(60) Provisional application No. 63/578,944, filed on Aug. 25, 2023.

(51) Int. Cl. H03M 1/10

(52) U.S. Cl. CPC H03M 1/1014

(57) ABSTRACT

There is provided a digital-to-analog converter, DAC. The DAC circuit comprises an input for receiving a digital input comprising a plurality of bits; an LSB transconductance stage; an MSB transconductance stage; a plurality of current sources, the plurality of current sources comprising a first current source and a second current source; and a switching circuit, the switching circuit configurable to modify a coupling between the plurality of current sources and the LSB transconductance stage and the MSB transconductance stage, wherein the switching circuit is configured to: couple the first current source to one of the LSB transconductance stage and the MSB transconductance stage, and couple the second current source to the other of the LSB transconductance stage and the MSB transconductance stage. A third, binary, transconductance stage may also be present.

### CROSS REFERENCE TO PRIORITY APPLICATION

Any and all applications for which a foreign or domestic priority claim is identified in the Application Data Sheet as filed with the present application are hereby incorporated by reference under 37 C.F.R. § 1.57. This application is a continuation-in-part of U.S. application Ser. No. 18/679,005, filed May 30, 2024 and titled “DIGITAL-TO-ANALOG CONVERTER,” which claims the benefit of priority of U.S. Provisional Application No. 63/578,944, filed Aug. 25, 2023 and titled “DIGITAL TO ANALOG CONVERTER,” disclosures of each which are hereby incorporated by reference in their entireties and for all purposes.

### TECHNICAL FIELD

The present disclosure relates to a method for controlling a digital-to-analog converter, and a digital-to-analog converter.

### BACKGROUND

Digital-to-analog converters, DACs, receive a digital input, code or word and generate an analog output signal. A segmented DAC may comprise multiple sections or DACs, each configured to convert a different part of the digital input. These parts may then be combined to provide the analog output of the DAC.

The digital input comprises one or more most significant bits (MSBs) and one or more least significant bits (LSBs). A segmented DAC may therefore comprise one or more most significant bit sections, acting to convert the MSBs of the digital input, and one or more least significant bit sections, acting to convert the one or more LSBs. The outputs of the MSB and LSB sections are then combined to provide the analog.

A segmented DAC may be based on one of a number of different DAC technologies, such as ladder DACs or string DACs. Based on how the MSB and LSB sections of the DAC are segmented, the size of the decoders and number of switches required may change. Further, segmentation of the DAC can impact the linearity and monotonicity of the system.

It is desirable to provide a DAC comprising a limited number of switches that has improved monotonicity.

### SUMMARY

There is provided a method for controlling a digital-to-analog converter, DAC.

According to a first aspect of the disclosure, there is provided a digital-to-analog converter, DAC, circuit comprising an input for receiving a digital input comprising a plurality of bits; an LSB transconductance stage; an MSB transconductance stage; a plurality of current sources, the plurality of current sources comprising a first current source and a second current source; and a switching circuit, the switching circuit configurable to modify a coupling between the plurality of current sources and the LSB transconductance stage and the MSB transconductance stage, wherein the switching circuit is configured to couple the first current source to one of the LSB transconductance stage and the MSB transconductance stage, and couple the second current source to the other of the LSB transconductance stage and the MSB transconductance stage.

According to a second aspect of the disclosure, there is provided a digital-to-analog converter, DAC, circuit comprising an input for receiving a digital input comprising a plurality of bits;
a plurality of differential pairs; a differential pair control circuit is configured to control a configurable coupling of each of the plurality of differential pairs such that they form part of an LSB transconductance stage or an MSB transconductance stage; a plurality of current sources, the plurality of current sources comprising a first current source and a second current source; and a switching circuit, the switching circuit configurable to modify a coupling between the plurality of current sources and the LSB transconductance stage and the MSB transconductance stage, wherein the switching circuit is configured to couple the first current source to one of the LSB transconductance stage and the MSB transconductance stage, and couple the second current source to the other of the LSB transconductance stage and the MSB transconductance stage.

According to a third aspect of the disclosure, there is provided a method for controlling a digital-to-analog converter, DAC, comprising a plurality of differential pairs and a plurality of current sources, the method comprising: controlling a configurable coupling of a plurality of differential pairs such that they form part of an LSB transconductance stage or an MSB transconductance stage; controlling a configurable coupling between a plurality of current sources and the LSB transconductance stage and the MSB transconductance stage, such that the first current source is coupled to one of the LSB transconductance stage and the MSB transconductance stage, and the second current source is coupled to the other of the LSB transconductance stage and the MSB transconductance stage.

### BRIEF DESCRIPTION OF THE DRAWINGS

FIG. 1 is a schematic diagram of a segmented DAC;

FIG. 2a is a schematic diagram of a segmented DAC system;

FIG. 2b is a schematic diagram of a resistor string forming part of the first stage of the DAC system of FIG. 2a;

FIG. 3 is a schematic diagram of a four-bit segmented DAC with multiple current sources;

FIG. 4 is a schematic diagram of a four-bit segmented DAC including a switching circuit;

FIG. 5 is a flowchart of a method for controlling a DAC;

FIG. 6a is a schematic diagram of a four-bit segmented DAC including a switching circuit coupling current sources in a first position;

FIG. 6b is a schematic diagram of a four-bit segmented DAC including a switching circuit coupling current sources in a second position;

FIG. 6c is a schematic diagram of a four-bit segmented DAC including a switching circuit coupling current sources in a third position;

FIG. 7 is a schematic diagram of a degeneration transistor coupled between a current source and a differential pair;

FIG. 8 is a schematic diagram of a DAC including a plurality of configurable differential pairs;

FIG. 9 is a schematic diagram of a DAC including a plurality of configurable differential pairs coupled in a first manner;

FIG. 10 is a schematic diagram of a DAC including a plurality of configurable differential pairs coupled in a second manner;

FIG. 11 is a schematic diagram of a DAC including a plurality of configurable differential pairs and a redundant differential pair;

FIG. 12 is a schematic diagram of a DAC including a plurality of configurable differential pairs and a differential pair calibration circuit;

FIG. 13 is a schematic diagram of a DAC including a plurality of configurable differential pairs and a redundant differential pair, with a modification in the coupling of the devices;

FIG. 14 is a schematic diagram of a DAC including a calibration current source and a current source calibration circuit 1472;

FIG. 15 is a schematic diagram of a DAC including a calibration current source coupled in parallel with a further current source;

FIG. 16 is a schematic diagram of a DAC including a calibration current source coupled in place of another current source;

FIG. 17 is a schematic diagram of a DAC comprising a binary stage;

FIG. 18 is a schematic diagram of an implementation of the binary stage; and

FIG. 19 is a flowchart of a method for controlling the operation of the DAC

### DETAILED DESCRIPTION

Segmented DACs comprise one or more most significant bit sections, acting to convert the MSBs of the digital input, and one or more least significant bit sections, acting to convert the one or more LSBs of the digital input. Based on how the MSB and LSB sections of the DAC are segmented, the size of the decoders and number of switches required may change.

A segmented DAC may comprise a thermometric LSB stage. Thermometric DACs guarantee monotonicity of the analog output. A fully monotonic DAC has an output that changes in the same direction as the input (e.g. when the input increases, the output of the DAC increases). The output of a non-monotonic DAC may change in the opposite way to the input (e.g. when the input increases, the output of the DAC decreases). It is desirable to provide DACs that are monotonic. However, typically, thermometric DACs require a large number of switches, taking up a large area. Further, the large number of switches increase other errors due to leakage. This limits the practical uses of thermometric segmented DACs, as a large DAC is required to provide a highly monotonic output.

It is desirable to provide a DAC comprising a limited number of switches that has improved monotonicity.

A DAC may include differential pair devices, with the sources of the differential pairs coupled to a current source. Changing the control signals that supply the gate voltages of the differential pairs results in a different current being drawn, providing an analog output that is related to the digital input. To improve device linearity, a number of current sources may be used, with a separate current source coupled to each differential pair. To provide a linear system, closely-matched input-differential pair devices and current sources are used. However, the greater the degree of matching between the current sources, the greater the area required to provide the current sources.

So as to provide a monotonic DAC in a small area, a switching circuit may be used to modify the coupling of the current sources. During a transition in the DAC input, a current source may be decoupled from a first transconductance stage providing an LSB portion of the DAC output and coupled to a second transconductance stage providing an MSB portion of the DAC output. This ensures that the same current source error is provided to the MSB transconductance stage as was provided to the LSB transconductance stage. Maintaining a consistent error during the transition of the DAC input ensures that the output transitions monotonically. This enables a compact DAC with a limited number of switches and monotonic output.

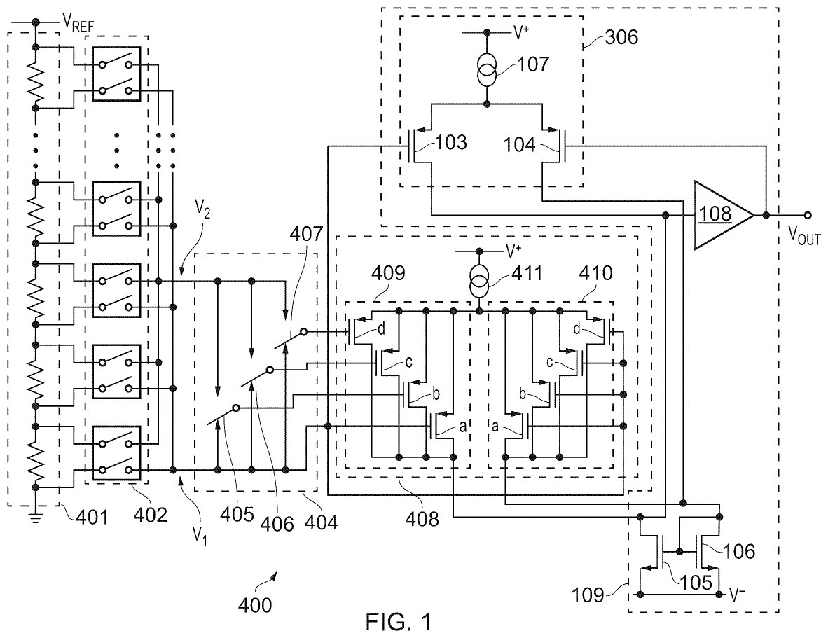

FIG. 1 is a schematic diagram of a DAC 400 comprising a resistor string or resistive device bank 401. The DAC 400 receives a digital input and generates an analog output. A switching device bank 402 comprises a plurality of switches coupled to the resistor string 401. The switches of the switching device bank 402 are controlled by the most significant bits (MSBs) of a digital input, with a particular two switches of the switching device bank 402 closed in dependence on the value of the MSBs. As such, the switching device bank 402 may be considered to be an MSB section of the DAC 400.

The MSB section 402 outputs two reference voltages (V1 and V2). The values of the voltages V1 and V2 are dependent on which switches of the MSB section 402 are closed, and therefore representative of the MSBs of the digital input word.

The voltages V1 and V2 are provided to a second switching device bank 404 comprising a plurality of switches 405, 406, 407. The switches of the second switching device bank 404 are controlled in dependence on the value of the least significant bits (LSBs) of the digital input word. As such, the second switching device bank 404 may be considered to be an LSB section of the DAC 400.

The plurality of switches of the LSB section 404 of the DAC 400 couple the voltages V1 and V2 from the MSB section 402 of the DAC to a transconductance stage 408. The transconductance stage 408 receives a plurality of output voltages from the LSB section 404 of the DAC and provides a proportional output current. The output voltages of the LSB section 404 are coupled to the gates of a plurality of transistors 409a-409d, which form part of transistor differential pair devices, of the transconductance stage 408. As such, the gates of the differential pairs are coupled to either V1 or V2, depending on the value of the LSBs. The sources of each of the plurality of transistors 409a-409d are coupled to a current source 411.

If the value of all the LSBs of the digital input are 0, then the switches 405-407 are all coupled to the voltage V1. This couples the voltage V1 to the gates of the plurality of transistors 409a-409d. If the value of all the LSBs of the digital input are 1, then the switches 405-407 are all coupled to the voltage V2. This couples the voltage V2 to the gates of the plurality of transistors 409b-409d. Changing the gate voltages of the plurality of transistors 409 results in a current being drawn from the current source 411 that is proportional to the number of transistors that are coupled to each of the voltages V1 and V2. This changes an output voltage of the DAC.

As such, the DAC 400 acts to provide an analog output based on the digital input.

The source terminals of the transistors of the transconductance stage 408 are coupled to a single current source 411. However, this introduces a non-linearity as the LSB code changes.

The DAC 400 shown in FIG. 1 comprises an MSB section 401/402 and an LSB section 404. The transconductance stage of the DAC 400 comprises a plurality of differential transistor pairs Q1, Q2, Q3. As noted, all of the differential transistor pairs are coupled to the same current source. Each transistor pair may instead be coupled to a respective, dedicated, current source.

Providing a plurality of current sources, such that each differential pair of the transconductance stage 408 is coupled to a separate, dedicated, current source substantially improves the linearity of the DAC 400.

The LSB decoder of the DAC 400 of FIG. 1 is thermometric, which guarantees that the DAC is monotonic. However, the DAC 400 of FIG. 1 requires a large number of switches due to how the DACs are segmented. For example, where the DAC is an 8-bit DAC, 256 switches are used in the MSB section and the LSB section. There is a need to reduce the number of switches in the DAC to reduce the total DAC size, whilst maintaining high monotonicity.

The DAC 400 of FIG. 1 includes two stages. The first stage outputs two reference voltages V1 and V2. The second stage receives these reference voltages and provides an analog output.

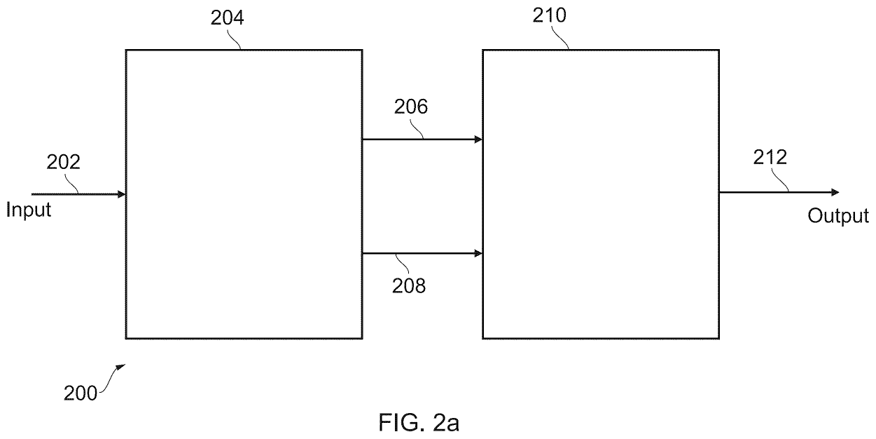

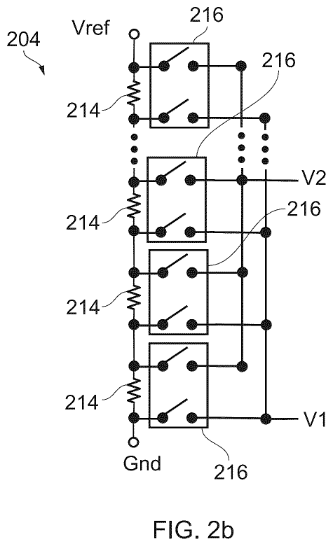

FIG. 2a is a schematic diagram of a DAC system 200. The DAC system 200 receives a digital input signal 202 at a first stage 204. The first stage 204 generates or provides two reference signals V1 206 and V2 208. The second stage 210 receives the reference signals 206, 208 and generates or provides an analog output signal 212.

FIG. 2b is a schematic diagram of a first stage 204 of the DAC system 200. The first stage 204 comprises a resistor string or impedance string, which comprises a plurality of resistors or impedances 214 coupled between a reference voltage Vref (for example the power supply voltage Vdd) and ground. Whilst ground is shown in the figure, it should be understood that any other reference voltage may be used in its place. A plurality of switching elements 216 (which may also be referred to as a switching bank) are coupled to the terminals of resistors 214.

As described with respect to FIG. 1, the switching elements 216 of the first stage 204 of the DAC are configured to switch in dependence on a number of bits of the digital input 202 so as to output a first voltage V1 and a second voltage V2. The values of the voltages V1 and V2 are dependent on which switches of 216 are closed. Controlling the switches coupled to the resistor string using a number of bits of the digital input results in the voltages V1 and V2 being representative of a number of bits of the digital input word. The second stage 210 of the DAC system 202 DAC may then receive the voltages V1 and V2 and configure the output in dependence on the values of the voltages V1 and V2 and in dependence on a different set of bits of the digital input.

Whilst FIG. 2b shows a resistor string, it should be understood that any suitable first stage 202 that generates reference voltages in dependence on a digital input may be used.

As noted with respect to FIG. 1, there is a need to improve the second stage 210 of the DAC system 200 to operate more efficiently, reducing the number of switches whilst maintaining high monotonicity. The following figures and description describe how the second stage 210 may be provided. The second stage 210 will be referred to as a DAC, as it receives a number of bits of the digital input and provides an analog output. The DAC acts to receive a digital input and interpolate between two reference values or voltages (V1 and V2) to provide the analog output. The DAC may also be considered to be a sub-DAC or substage.

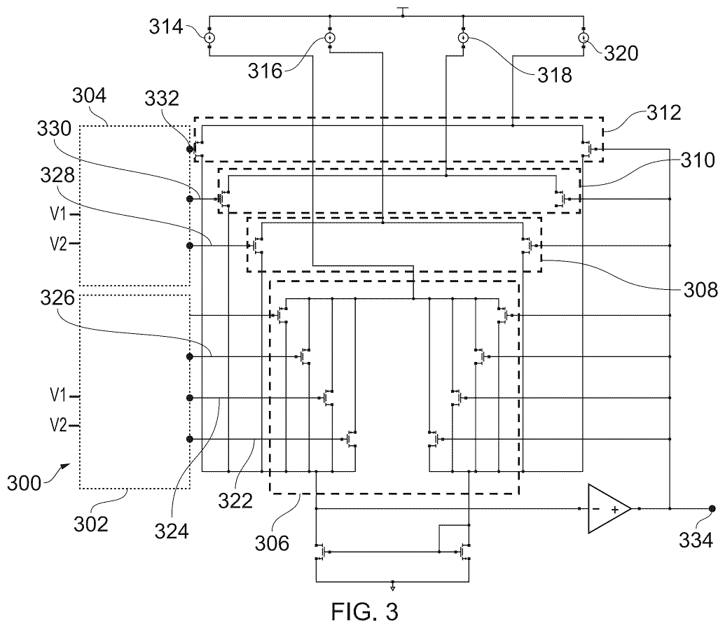

FIG. 3 is a schematic diagram of a DAC 300 including two sections, which may be used as the second stage 210 of the DAC 200, or independently as a separate DAC. The DAC comprises an LSB section 302 configured to receive the least significant bits of a digital input and an MSB section 304 configured to receive the most significant bits of the digital input. The LSB section acts to convert the LSBs of the digital input into a first analog signal and the MSB section acts to convert the MSBs of the digital input into a second analog signal. These respective analog outputs may then be combined to provide the analog output of the DAC. The digital input provided to the DAC 300 may be a whole digital word, or part of a digital word, where the remainder of the digital word is represented by the values of the reference voltages V1 and V2.

The DAC 300 is a four-bit DAC configured to split the digital input into two least significant bits and two most significant bits. However, it should be understood that the DAC may be configured to receive inputs with a different number of bits, such as 8 bits, 16 bits or 32 bits. Similarly, the boundary between the least significant bits and most significant bits may be modified, such that different proportions of the digital input word are considered to be MSBs or LSBs.

The LSB section 302 and the MSB section 304 receive a first reference voltage V1 and a second reference voltage V2 (for example from the first stage 202 of the DAC 200, or any other suitable source such as a resistor string). These reference voltages may be any suitable value. For example, the first reference voltage may be ground or 0 v, and the second reference voltage may be a voltage rail or power supply voltage of the system. Alternatively, the reference voltages may be generated in a first stage 204 of a DAC system 200 based on a number of bits of a digital input 202. Any two different reference voltages may be used.

The LSB section 302 receives the LSBs of the digital input and generates a plurality of output control signals. Similarly, the MSB section 304 receives the MSBs of the digital input and generates a plurality of output control signals. The output control signals may be DC signals and have voltages equal to either the first reference voltage V1 or the second reference voltage V2.

The output control signals are outputted by the LSB section 302 and the MSB section 304 to respective transconductance stages or elements 306, 308, 310, 312. The LSB section 302 provides output control signals to a first or LSB transconductance stage 306. The MSB section 304 provides output control signals to one or more transconductance stages. In the system of FIG. 3, this comprises a first MSB transconductance stage 308, a second MSB transconductance stage 310 and a third MSB transconductance stage 312.

Systems which operate on a larger number of bits may have a different number of MSB transconductance stages. For example, where the digital input comprises X most significant bits, the DAC may comprise 2^{X}-1 MSB transconductance stages.

The transconductance stages comprise one or more differential transistor pairs. The sources of the differential pairs in each transconductance stage are coupled to respective current sources, 314-320. Each transconductance stage is coupled to a dedicated current source. The gates of one of the transistors in each differential pair is coupled to a respective output control signal provided by the LSB section 302 or the MSB section 304. When the output control signals provided to the gates of the differential pairs transition from V1 to V2 (or vice versa depending on whether the transistors are N-type or P-type transistors) the current drawn from the respective current source changes and the output voltage of the DAC, generated at output terminal 334, changes. The gates of the second one of the transistors in each differential pair are coupled to an output node or output terminal 334.

These ‘transconductance stages’ have devices in their linear region of operation by having the two input voltages, V1 & V2, being sufficiently close that the respective current source is only partially steered in favour of one direction (one MOS drain) or the other, and the degree of current steering is substantially proportional to the voltage difference (V1−V2). The transconductance of such a stage can be considered to be the ratio of this proportionality, that is the degree of current steering divided by the voltage difference (V1−V2). This is in contrast to the principle of a conventional current-steering DACs, in which each current source is entirely switched to one output or the other.

The LSB section 302 and LSB transconductance stage 306 act to convert the Y LSBs of the digital input to a first analog signal. The MSB section 304 and one or more MSB transconductance stages 308-312 act to convert the X MSBs of the digital input to a second analog signal. The combination of these analog signals provides the analog output signal of the DAC 300.

The LSB transconductance stage 306 comprises four differential transistor pairs, with the sources of the differential pairs coupled to a first current source 314. The number of differential transistor pairs within the LSB transconductance stage is dependent on the number of LSBs. In the four-bit example of FIG. 3, two bits may be LSBs and two bits may be MSBs. Four differential transistor pairs are provided in the LSB transconductance stage 306. Where there are Y LSBs, 2^{Y} differential pairs may be provided in the LSB transconductance stage. The sources of the differential pairs of the transconductance stage are coupled to the same first current source 314. Each of the differential pairs of the LSB transconductance stage can be independently controlled by a respective output control signal of the LSB section 302.

The LSB transconductance stage 306 of FIG. 3 includes 2^{Y} differential pairs (4 differential pairs) however it should be understood that 2^{Y-1} (3 differential pairs) may be used instead in another example.

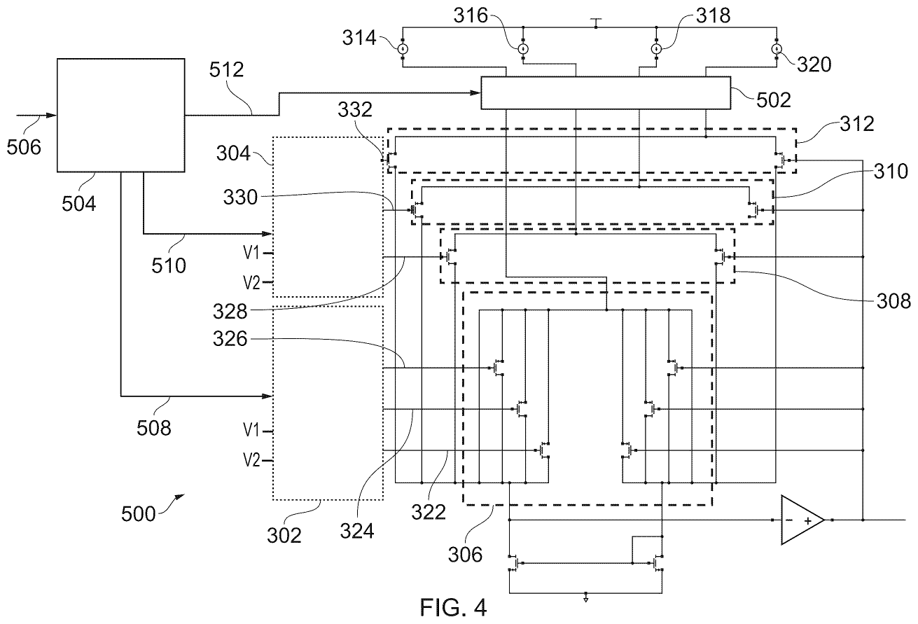

The use of 2^{Y} differential pairs allows the LSB transconductance stage 306 to provide an output resolution in steps of 1/2^{Y} (depending on the number of differential pairs that are switched on). When all switches are on (or connected to reference voltage V2), the output value of the LSB transconductance stage 306 is 2^{Y}. When all the differential pairs are off (or connected to reference voltage V1), the output value of the LSB transconductance stage 306 is 0. As such, the value of 2^{Y} may be provided by the LSB transconductance stage 306 or by one of the MSB transconductance stages 308-312. The LSB transconductance stage may instead include 2^{Y}-1 differential pairs. The LSB transconductance stage may provide values of 0, 1 . . . 2^{Y}-1. Where there are 2^{Y}-1 differential pairs (which would be three differential pairs in four-bit DAC, as shown in FIG. 4), the value of zero may be represented by none of the differential pairs being turned on (or all coupled to V1). Using 2^{Y}-1 differential pairs reduces the number of differential pairs required in the system. As such, where the DAC 300 is discussed further in this application, only 2^{Y}-1 differential pairs are included in the LSB transconductance stage 306.

The MSB transconductance stages 308-312 each comprise a differential transistor pair coupled to a respective current source. The first MSB transconductance stage 308 includes a differential pair with the sources coupled to the second current source 316. The second MSB transconductance stage 310 includes a differential pair with the sources coupled to a third current source 318. The third MSB transconductance stage 312 includes a differential pair with the sources coupled to a fourth current source 320.

Each of the transconductance stages is therefore coupled to a dedicated current source.

Each of the transistors included in the differential pairs of the MSB transconductance stages 308, 310, 312 has a width-to-length (W/L) ratio that is four times the width-to-length ratio of the differential pairs of the LSB transconductance stage 306. In this way, the differential pairs of the MSB transconductance stages have higher transconductance and allow a greater current to flow for the same gate voltage compared to the differential pairs of the LSB transconductance stage 306. As such, changing one of the output control signals from the MSB section 304 from V1 to V2 has a greater impact on the output of the DAC than changing one of the output control signals from the LSB section 302 from V1 to V2.

In this way, if three of the differential pairs of the LSB transconductance stage 306 are turned on, the output of the DAC 300 is representative of a value of three (where the binary input is 0011). If a single one of the MSB transconductance stages is turned on, the output of the

DAC is representative of a value of four (where the binary input is 0100). Any binary input between 0000 and 1111 can be represented by turning on and off differential pairs of the transconductance stages. Where the binary input is 0000, all of the differential pairs receive an output control signal of V1 from the MSB and LSB sections. Where the binary input is 1111, all of the differential pairs receive an output control signal of V2 from the MSB and LSB sections.

Whilst the transistors of the MSB transconductance stages 308, 310, 312 of the example of FIG. 3 have a W/L ratio four times greater than the W/L ratio of the, this ratio may be different depending on the number of bits which are considered LSBs. As such, where the binary input has Y LSBs, the W/L ratio of the differential pairs of the MSB transconductance stages is 2^{Y} times that of the W/L ratio of the differential pairs of the LSB transconductance stage 306. Alternatively, each MSB transconductance stage may comprise a number of differential pairs connected in parallel, with the gates of the parallel differential pairs connected to the same output control signal from the MSB section 304. For example, the differential pair of the first MSB transconductance stage 308 may be replaced with four differential pairs coupled in parallel to the same output control signal of the MSB section 304, each of the differential pairs having the same W/L ratio as the differential pairs of the LSB transconductance stage.

The MSB section 304 and the LSB section 302 of FIG. 3 may comprise a plurality of multiplexers configured to receive control signals dependent on the digital input signal of the DAC 300 and provide output control signals to the transconductance stages in dependence on the value of the digital input. The LSB section and MSB section may be implemented using other circuitry, such as control circuitry or transistors.

When the digital input of the DAC 300 transitions from a value of 2^{Y}-1 to a value of 2^{Y}, the outputs control signals transition from V2 to V1 for all the differential pairs of the LSB transconductance stage 306, and one output control signal of the MSB section 304 transitions from V1 to V2.

In a four-bit example, with two MSBs and two LSBs, this is a change in the digital input from 0011 to 0100.

The output of the DAC was provided by the LSB transconductance stage 306 and thus dependent on the first current source 314. With the change in the digital input, the output of the DAC 300 transitions to being provided solely by the first MSB transconductance stage 308 and the second current source 316. Ideally, the current sources coupled to the DAC transconductance stages would be the same. However, as in any circuit, there may be an error or variance in the current provided by the current sources. If this error is large enough, and the second current source 316 has a significantly lower value than the first current source 314, then the transition of the digital input from 0011 to 0100 may cause a decrease in the output of the DAC. As such, the DAC may not have a fully monotonic output when the system transitions between the use of the LSB section 302 and the MSB section 304.

In a four-bit example, if the second current source 316 provides a current that is ¼^{th} lower than the first current source 314, the output will not increase when the LSB transconductance stage 306 is turned off and the first MSB transconductance stage 308 is turned on. This results in a non-monotonic output in DACs with a larger number of LSBs, wherein a smaller percentage variance between the current sources causes a non-monotonic change in the output. For example, where there are four LSBs, a 1/16^{th} variance in the current provided by the current sources can provide a non-monotonic change in the output.

The DAC of FIG. 3 allows the use of less switches when compared to the DAC of FIG. 1, as each of the MSB transconductance stages requires a single differential pair to represent a 2^{Y} increase in the digital input. However, the LSB section is not thermometric. Due to the segmentation of the DAC, the DAC is no longer inherently monotonic. This lack of monotonicity is particularly pronounced at every 2^{Y}-1 to 2^{Y} transition in the input code of the DAC, when all the differential pairs of the LSB transconductance stage switch at the same time as one of the MSB transconductance stages switching.

It is desirable to provide a DAC with a reduced number of switches, as in the DAC 300, whilst improving the monotonicity of the output.

FIG. 4 is a schematic diagram of a DAC system 500. The DAC system includes a number of features described with respect to FIG. 3 and as such these features will not be described again. The DAC 500 includes a switching circuit 502 coupled between the plurality of current sources 314-320 and the transconductance stages 306-312 of the DAC 500. As noted previously, the LSB transconductance stage 306 of FIG. 4 includes three differential pairs, however four differential pairs could be used instead (as shown in FIG. 3).

The switching circuit 502 is configured to switchably connect each of the current sources 314-320 to a respective transconductance stage of the plurality of transconductance stages 306-312.

The switching circuit 502 may comprise any suitable switching circuitry, such as a plurality of switches, a plurality of switching elements or one or more multiplexers. The switches or switching elements may comprise one or more transistors, such as MOSFETs. However, other suitable transistor types may be used.

The DAC 500 comprises a control system 504. The control system 504 is configured to receive a digital input 506 for conversion by the DAC 500. The control system generates one or more LSB section control signals 508 and one or more MSB section control signals 510. The LSB 508 and MSB 510 section control signals control the operation of the LSB and MSB sections in dependence on the digital input 506. As such, the output control signals 322-332 of the LSB and MSB sections are controlled by the LSB control signal 508 and the MSB control signal 510.

The control system 504 is further configured to generate a switching circuit control signal 512. The switching circuit control signal 512 controls the configuration of the plurality of switching elements within the switching circuit 502. As such, the switching control signal 512 may configure the switching circuit 502 to couple or decouple the current sources 314-320 of the DAC 500 to or from respective LSB 306 or MSB 308-312 transconductance stages.

The control system 504 shown in FIG. 4 is a separate element, however the control system may be integrated with one or more of the LSB section 302 and the MSB section 304.

The control system 504 may comprise one or more processors and a memory. The processor may be configured to read from the memory. Alternatively, the control system may comprise logic circuits or other control means.

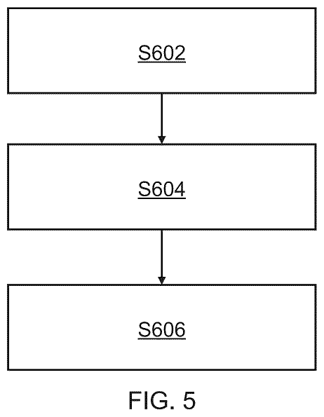

FIG. 5 is flowchart of a method for controlling the DAC 500. The method may be performed by the control system 504 of the DAC 500, or the control system of any suitable DAC.

Step S602 comprises receiving a digital input comprising a plurality of bits. The digital input includes a first segment comprising X most significant bits, MSBs, and a second segment comprising Y least significant bits, LSBs. The number of bits that are considered to be MSBs and LSBs may be determined at manufacture of the device. Any number of MSBs or LSBs may be used. Typically, the digital input may comprise 4, 8, 16, 32, 64, or 128 bits. Half of the bits of the digital input may be MSBs and half LSBs, however, any proportion of the bits of the digital input may be LSBs, such as 25%, 50%, 75%.

The digital input may change over time. Step S604 comprises detecting a change in the value of the digital input compared to a previous value of the digital input. Where the digital input changes such that the value of the MSBs change, and the LSBs change by a value of 2^{Y}-1, an error may occur. As described previously, where the value of the LSBs change from 2^{Y}-1 to 0 and the value of the MSBs increase by 2^{Y}, then the output of the DAC transitions from being provided by (at least partly) the LSB transconductance stage 306 to being provided by one or more of the MSB transconductance stages 308-312.

Step S606 comprises modifying the couplings between the current sources 314-320 and the transconductance stages 306-312. Modifying the coupling comprises decoupling current sources from respective transconductance stages and coupling the decoupled current sources to alternative transconductance stages. Step S606 comprises decoupling the first current source 314 from the LSB transconductance stage 306 and coupling the first current source 314 to the first MSB transconductance stage 308.

Modifying the coupling of the first current source 314 in this way ensures that the same current source error that was provided to the LSB transconductance stage 306 is provided to the first MSB transconductance stage 308 when the digital input changes in such a way that the output is provided by the MSB transconductance stage 308 and not by the LSB transconductance stage 306. This ensures that the transition between the transconductance stages maintains a monotonic output, as the same current source error is present in the output. If the current sources were not changed, then current source variance may result in the output decreasing even when the DAC 500 input increases.

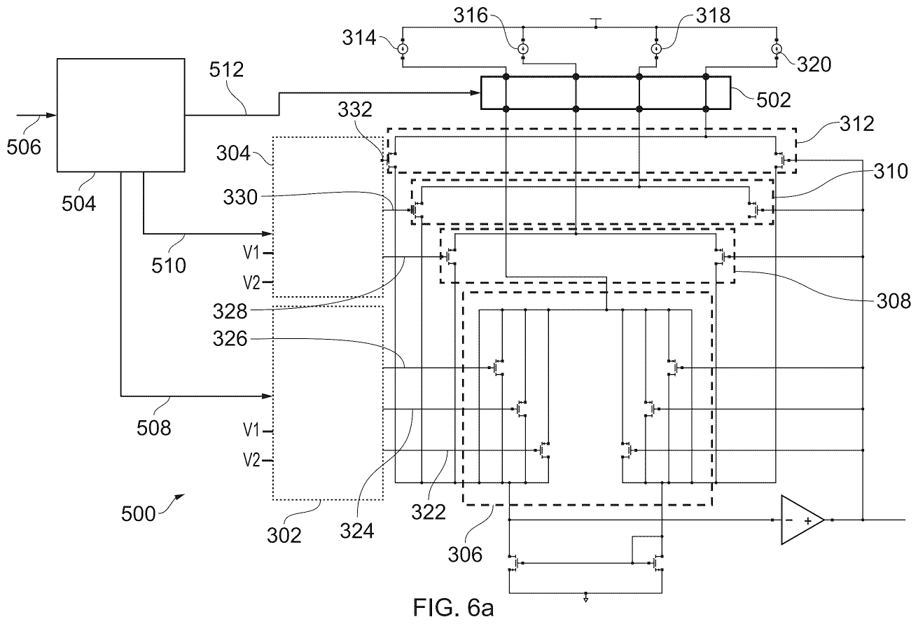

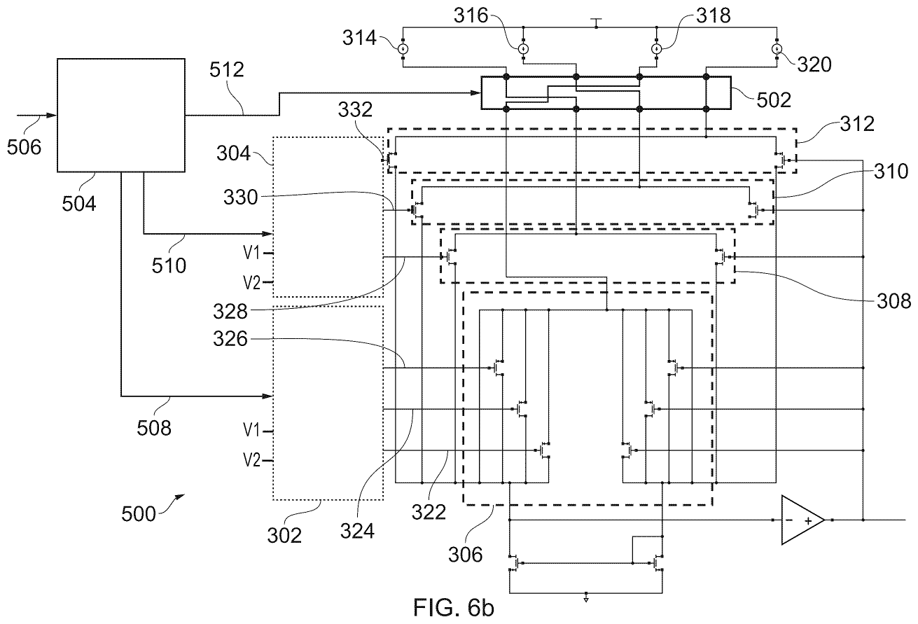

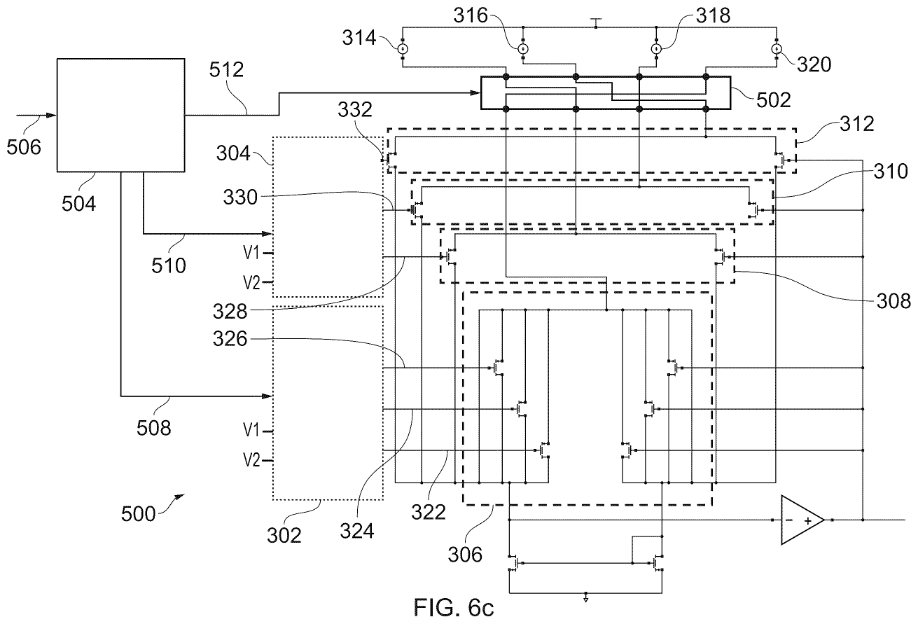

FIG. 6a shows a first configuration of the DAC 500, with the connections provided by the switching circuit 502 presented for ease. Whilst these connections are shown as simple direct connections, this is for ease of understanding only. Instead, the connections may be provided by one or more switches or switching elements within the switching circuit.

The first current source 314 is coupled to the LSB transconductance stage 306. The second current source 316 is coupled to the first MSB transconductance stage 308. The third current source 318 is coupled to the second MSB transconductance stage 310. The fourth current source 320 is coupled to the third MSB transconductance stage 312.

With a four-bit input, including two LSBs and two MSBs, the digital input may be 0011. As such, output control signals 322-326 may have a value of V2. Output control signals 328-332 may have a value of V1.

If the digital input changes to 0100, output control signals 322-326 and 330-332 have a value of V1. Output control signal 328 has a value of V2.

FIG. 6b shows a second configuration of the DAC 400.

To ensure the same error is present in the output, the first current source 314 is decoupled from the LSB transconductance stage 306 and is coupled to the first MSB transconductance stage 308.

To ensure that all the transconductance stages are coupled to a current source, the second current source 316 is decoupled from the first MSB transconductance stage 308 and is coupled to the second MSB transconductance stage 310. The third current source 318 is decoupled from the second MSB transconductance stage 310 and is coupled to the LSB transconductance stage 306.

The DAC 400 input may change from 0100 to 0111. No change is required in the coupling of the current sources to provide this transition, as it does not require the switching of an MSB transconductance stage. As such, the switching circuit 402 may continue to couple the same current sources and transconductance stages as shown in FIG. 6b.

If the digital input transitions from 0111 to 1000, a similar error may be present. The output control signals 322-326 and 332 have a value of V1. Output control signals 328 and 330 have a value of V2. As such, the analog output is provided by two of the MSB transconductance stages, with the second MSB transconductance stage 310 turning on, and the LSB transconductance stage 306 turning off.

FIG. 6c shows a third configuration of the DAC 400.

As such, the third current source 318 is decoupled from the LSB transconductance stage 306 and is coupled to the second MSB transconductance stage 310. The first current source 314 remains coupled to the first MSB transconductance stage 308. The second current source 318 is decoupled from the second MSB transconductance stage 310 and is coupled to the third MSB transconductance stage 312. The fourth current source 320 is decoupled from the third MSB transconductance stage 312 and is coupled to the LSB transconductance stage 306.

As the value of the digital input increases, different current sources will be coupled to the LSB transconductance stage 306. Each time there is a transition in the digital input such that the LSBs decrease in value by a maximum possible amount (i.e. all ones to all zeros, or a change of 2^{Y}-1) the current source coupled to the LSB transconductance stage will be coupled to an MSB transconductance stage which sees a transition in its control signal and turns on.

Whilst the possible error has been discussed with respect to a decrease in the value of the LSBs and an increase in the value of the MSBs, an error may also occur where there is a one bit decrease in the digital input. Where there is a decrease in the value of the MSBs by more than 2^{Y} and a change in the value of the LSBs from 0 to 2^{Y}-1, the error may occur. For example, where there are two MSBs and two LSBs in a four-bit digital input and the digital input changes from 1100 to 1011, an MSB transconductance is turned off, and all of the differential pairs of the LSB transconductance stage are turned on.

As such, a current source is decoupled from the MSB transconductance stage that is turned off and is coupled to the LSB transconductance stage.

Switching the current sources in the described manner offers a significant improvement in the differential non-linearity (DNL) of the DAC. A small number of additional switching elements are required to provide this improvement and limited additional logic circuitry. The logic or control circuitry used to operate the MSB and LSB sections can be reconfigured to also provide control of the switching circuit 502, as the switching circuit transitions at the same time as the output control signals of the MSB and LSB sections transition.

To reduce integral non-linearity (INL) of the DAC 400, the transconductance of the transconductance stages may be reduced. However, this increases the noise in the analog output and alters the offset of the DAC. With the segmented DAC presented in FIG. 4, the linearity is determined by the LSB section.

To improve the INL of the system, the differential pairs of the LSB transconductance stage 306 may be degenerated.

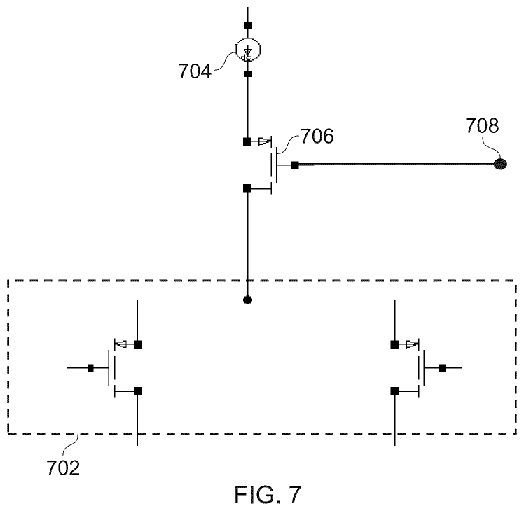

FIG. 7 shows a first differential pair of transistors 702. The differential pair 702 may represent one of the differential pairs of the LSB transconductance stage 306. As described previously, a current source 704 is coupled to the LSB transconductance stage, and in particular to the sources of the transistors of the differential pairs 702 of the LSB transconductance stage 306. The switching circuit 502 and the remaining transconductance stages and differential pairs of the DAC 400 are not shown in FIG. 7 for simplicity, however it should be understood that the differential pair and circuitry of FIG. 7 could be included in the DAC 400 of FIG. 4.

A degeneration transistor 706 is coupled between the current source 704 and the differential pair 702. The switching circuit 502 would be coupled between the current source 704 and the degeneration transistor 706.

The gate of the degeneration transistor 706 is coupled to the output 334 of the DAC. The degeneration transistor 706 is specified to have a width to length ratio that is smaller than that of the differential pairs 702 of the LSB transconductance stage. The W/L ratio of the degeneration transistor 706 may be substantially smaller than the W/L ratio of the differential pairs of the LSB transconductance stage 306. For example, the W/L ratio of the degeneration transistor 706 may be ¼, ⅛, 1/16, 1/32, 1/64, etc. of the W/L ratio of the differential pairs of the LSB transconductance stage 306. The degeneration transistor 706 may be a MOSFET held in the linear region of operation.

The degeneration transistor 706 is shown coupled to one differential pair of the LSB transconductance stage 306, however the degeneration transistor may be coupled to all of the differential pairs of the LSB transconductance stage 306.

Including the degeneration transistor significantly improves the INL of the DAC 300. Due to the structure of the DAC, the degeneration only has to be applied to the LSB transconductance stage 306, because the LSB transconductance stage 306 has the greatest impact on DAC linearity.

Whilst a single degeneration transistor may be used, alternatively a respective cascode transistor may instead be coupled between the switching circuit 502 and each of the differential pairs of the LSB transconductance stage 306. The cascode transistors ensure that the current from the current source coupled to the LSB transconductance stage 306 is split equally among each of the differential pairs of the LSB transconductance stage 306.

As described with respect to FIG. 2a, the DAC system 200 receives a digital input signal 202 at a first stage 204. The first stage 204 generates or provides two reference signals V1 206 and V2 208. The second stage 210 receives the reference signals 206, 208 and generates or provides an analog output signal 212.

The second stage 210 may be provided using any of the circuits described with respect to FIGS. 3-7. These systems may be statically encoded, in which the connections of the differential pairs are fixed for a given DAC code. The connections of the differential pairs (i.e. which differential pairs make up the respective MSB and LSB transconductance stages) may be determined during manufacture of the system. This may be through the use of hard-wired connections between the differential pairs or programming a configurable connection between the devices during manufacture. Further, the connections between the current sources may not change unless there is a specific change in value of the input to the stage of the DAC system if they are statically encoded.

Rather than statically encoding the DAC system, the devices that make up the DAC system may be configurably coupled such that the differential pairs that make up the LSB transconductance stage and the MSB transconductance stage can be modified. The configurable coupling may also apply to the coupling between the plurality of current sources and the transconductance stages. Providing a dynamically encoded DAC system may improve operation and accuracy of the DAC, for example by allowing devices with outlier properties to not be used or used in a different manner.

The DAC may additionally or alternatively comprise a binary (or near binary) transconductance stage. The plurality of current sources coupled to the LSB and MSB transconductance stage may be unary current sources of substantially the same value and may therefore be referred to as unary current source stage of the DAC. The binary input or transconductance stage may be coupled to a current source with a binary or substantially binary weighted value. The binary transconductance stage comprises a plurality of differential pairs, including one differential pair per bit of resolution. Whilst this increases the number of devices required in the DAC system, it may desirably provide increased DAC resolution.

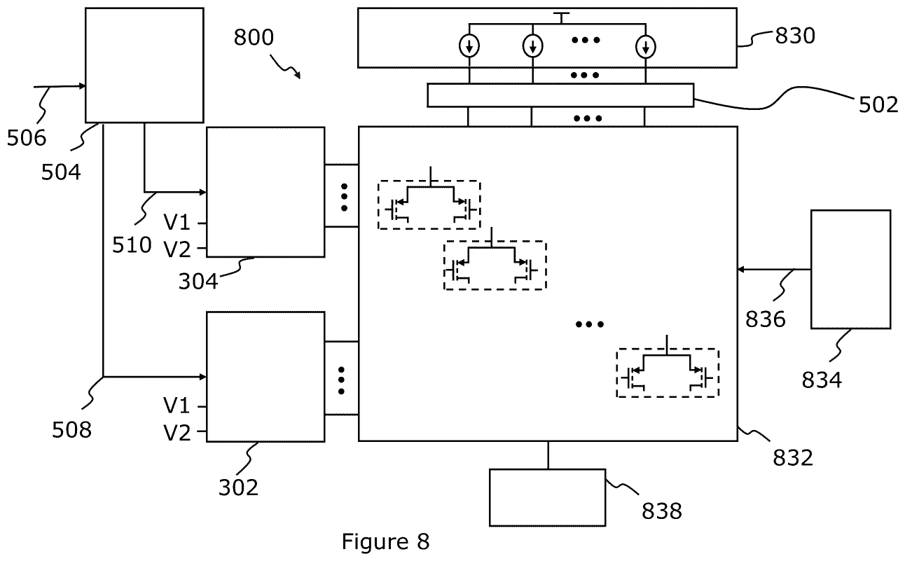

FIG. 8 is a schematic diagram of a DAC system 800. The DAC system 800 comprises a number of elements or components that correspond to those described with respect to the earlier figures, which will not be described in detail here for the sake of brevity. However, it should be understood that the earlier description is relevant to the following figures and like reference numerals are used to refer to like components.

DAC system 800 comprises a plurality of current sources 830 coupled to a plurality of differential pairs 832 via or through a switching circuit 502. The switching circuit 502 controls the coupling of the plurality of current sources 830 and the plurality of differential pairs 832 such that different ones of the plurality of current sources 830 may be coupled to different ones of the plurality of differential pairs 832.

The couplings of the plurality of differential pairs 832 are configurable, such that the differential pairs may be configured to act as part of different MSB or LSB transconductance stages respectively. As such, the couplings are not shown in FIG. 8. The configurable coupling of each of the plurality of differential pairs 832 is controlled using a differential pair control circuit 834 that outputs a differential pair control signal 836 to the plurality of differential pairs 832. It should be understood that any suitable switching arrangement may be included within or coupled to the plurality of differential pairs 832. As such, the differential pair control signal 836 may control the switching arrangement to couple the plurality of differential pairs to one another and to a suitable control output from the MSB section 304 and/or the LSB section 302. The control outputs from the MSB section 304 and LSB section 302 are reference voltages V1 and V2 which may be provided by an earlier stage of the DAC system, as previously explained.

The plurality of differential pairs 832 may comprise two or more differential pairs. The number of differential pairs may depend on the resolution of the DAC system 800. As noted previously, the plurality of differential pairs 832 used in the LSB transconductance stage may have a different width to length ratio compared to that of the differential pairs 832 used in the MSB transconductance stages. As such, the plurality of differential pairs 832 may comprise a plurality of differential pairs having different width to length ratios.

The DAC 800 further comprises an output stage 838 coupled to the plurality of differential pairs. The output stage 838 may be any suitable output stage the is coupled to the differential pairs 832 and configured to provide an analog output signal of the DAC.

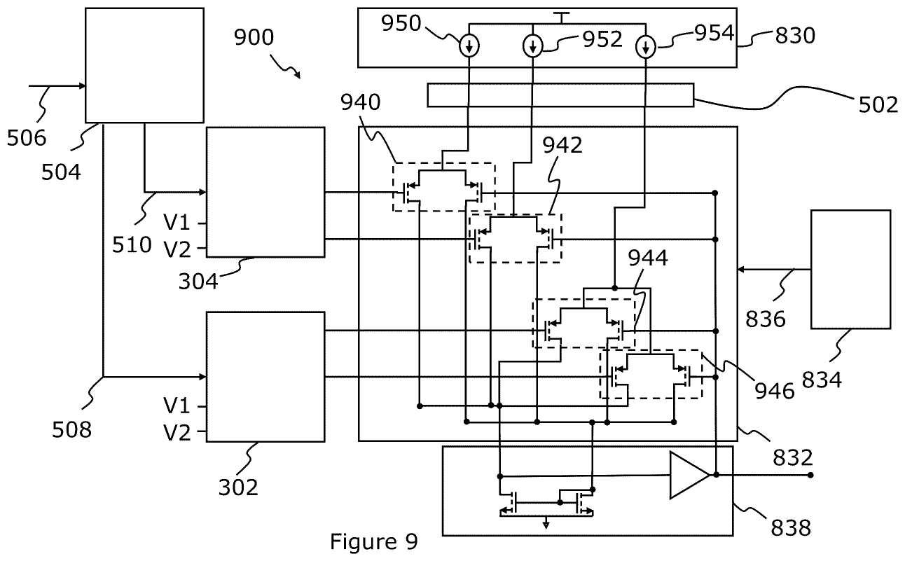

FIG. 9 is a schematic diagram of a DAC system 900. The plurality of differential pairs 832 comprise a first differential pair 940, a second differential pair 942, a third differential pair 944 and a fourth differential pair 946. The plurality of current sources 830 comprises a first current source 950, a second current source 952 and a third current source 954. The number of current sources and differential pairs shown in the DAC system 900 should be understood to be an example, and a different number of current sources and/or differential pairs may be provided depending on the resolution of the DAC system 900.

The differential pair control circuit 834 is configured to output the differential pair control signal 836 to control the coupling of the differential pairs 832 such that different subsets of the differential pairs 832 form part of an LSB transconductance stage or one or more MSB transconductance stages. Put another way, the LSB transconductance stage and the one or more MSB transconductance stage each comprise a respective subset of the differential pairs 832. Each respective subset may comprise one or more differential pairs.

As shown in FIG. 9, the first differential pair 940 is coupled to form part of a first MSB transconductance stage, forming a first subset of the differential pairs. The second differential pair 942 is configured to form part of a second MSB transconductance stage, forming a second subset of the differential pairs. As such, the first differential pair 940 and the second differential pair 942 are coupled to the MSB section 304 to receive the first reference voltage and second reference voltage.

The third differential pair 944 and the fourth differential pair 946 are coupled to form part of the LSB transconductance stage, forming a third subset of differential pairs. As such, the third differential pair 944 and the fourth differential pair 946 are coupled to the LSB section 302 to receive the first reference voltage and second reference voltage.

The differential pairs are also coupled to the current sources 830 via the switching circuit 830 and to output stage 838.

The coupling of the differential pairs shown in FIG. 9 is just one example of how the respective subsets of differential pairs may be implemented. The subsets of each transconductance stage may be modified by the differential pair control circuit 834. For example, the differential pairs that form part of each subset may be modified by the differential pair control circuit 834.

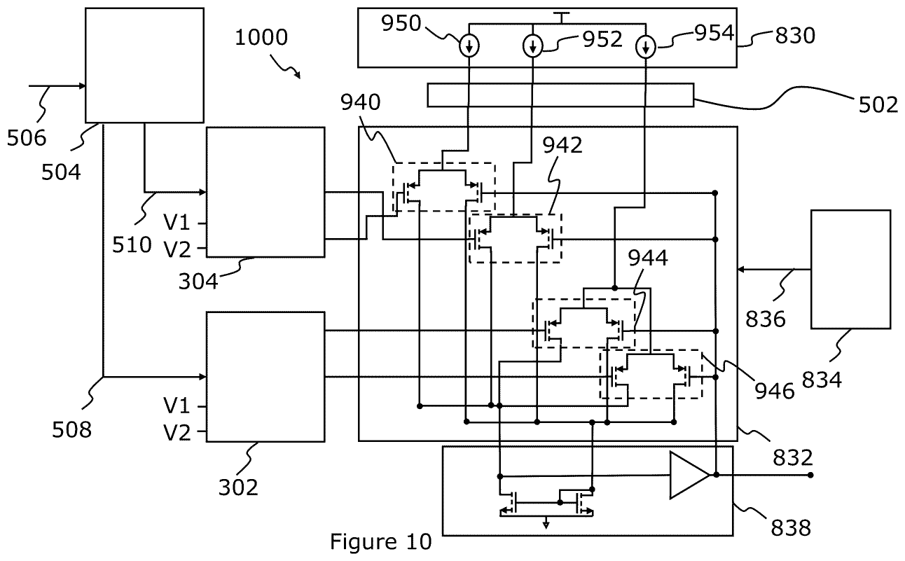

FIG. 10 is a schematic diagram of a DAC system 1000. The coupling of the first differential pair 940 and the second differential pair 942 are modified compared to the coupling shown in FIG. 9. In particular, the first differential pair 940 forms part of the second MSB transconductance stage and the second differential 942 forms part of the first MSB transconductance stage. This is shown by the control signals from the MSB section 304 being switched. The change in coupling is shown separate to the MSB section 304, however this is for ease of illustration. The change in coupling may instead be provided internal to the MSB section and/or LSB section 302. This may comprise changing which control signal is provided to each of the differential pairs. As such, the change in coupling of the devices may be provided without any physical change in connectivity but instead be provided by a change in the control signal provided to the differential pairs. Any suitable control circuit may provide the change in the control signals coupled to each of the differential pairs.

As such, the respective subsets of differential pairs in each of the MSB transconductance stages are modified by the differential pair control circuit to comprise different differential pairs of the plurality of differential pairs 832. The subsets which the differential pairs form part of have therefore been modified.

Notably, the third subset of differential pairs (including the third differential pair 944 and the fourth differential pair 946) are not modified between FIGS. 9 and 10. However, it should be understood that any of the subsets may be modified, be these subsets making up the MSB or LSB transconductance stages.

The respective subsets may be selected by the differential pair control circuit 834 based on any of a number of reasons, such as dynamic element matching, ordered element matching, machine learning or the removal of outlier devices, as described in further detail below.

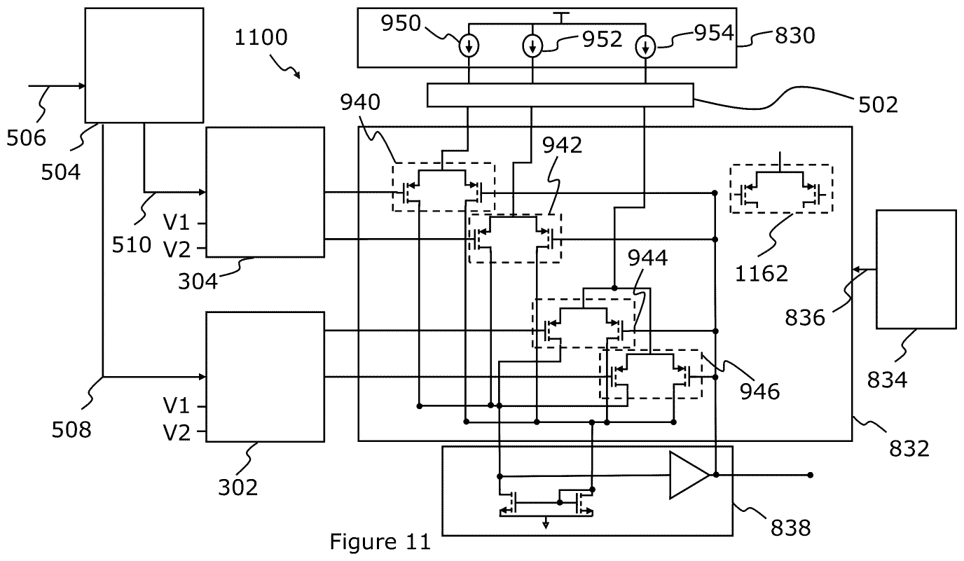

FIG. 11 is a schematic diagram of a DAC system 1100. The plurality of differential pairs 832 comprise an additional or redundant differential pair 1162 which is not coupled as part of the subsets of differential pairs included in the transconductance stages. As such, the redundant differential pair is not used to provide an output of the DAC. Whilst one redundant differential pair 1162 is shown in FIG. 11, it should be understood that a plurality of redundant differential pairs may be present. Further, the redundant differential pairs may comprise differential pairs with different width to length ratios. The redundant differential pairs may comprise replica devices of the plurality of differential pairs, with the same design, layout and width and length sizes and ratios. This allows the differential pairs coupled as part of the subsets of the LSB and MSB transconductance stages to be modified. Whilst reference has been made to the width to length ratios of the devices, it should be understood that the differential pairs and redundant differential pairs may also have matched values when compared to one another. For example, a number of parameters or unit sizings of the devices may be matched.

Redundant differential pair 1162 is shown as not being coupled to the output stage 838, to the plurality of current sources 830, to the switching circuit 502 or to the MSB 304 and LSB 302 sections. However, it should be understood that the redundant differential pair is couplable to these portions of the DAC 1100. Further, the redundant differential pair 1162 may be coupled to one or more portions of the DAC 1100 even when it is acting as a redundant device. For example, the differential pair 1162 may be coupled to the switching circuit 502 and the switching circuit 502 may act to decouple the redundant differential pair 1162 from the plurality of current sources 830.

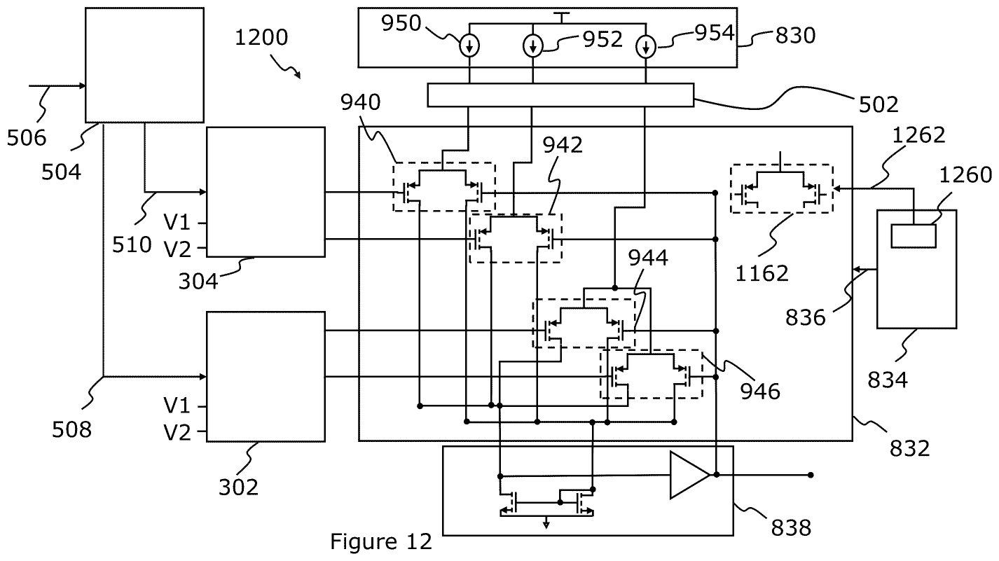

FIG. 12 is a schematic diagram of a DAC system 1200. During operation of the DAC, the differential pair control circuit 834, or more specifically a calibration or remapping circuit 1260 of the differential pair control circuit 834, may monitor or determine one or more properties of the redundant differential pair 1162. This may comprise applying a test or calibration signal to the redundant differential pair 1162. As the redundant differential pair is not being used to provide an output of the DAC, the remapping circuit may operate in the background whilst the remaining, non-redundant, differential pairs are acting to provide the output of the DAC system 1100. This allows continuous or periodic monitoring of the properties of one or more differential pairs without impairing DAC operation.

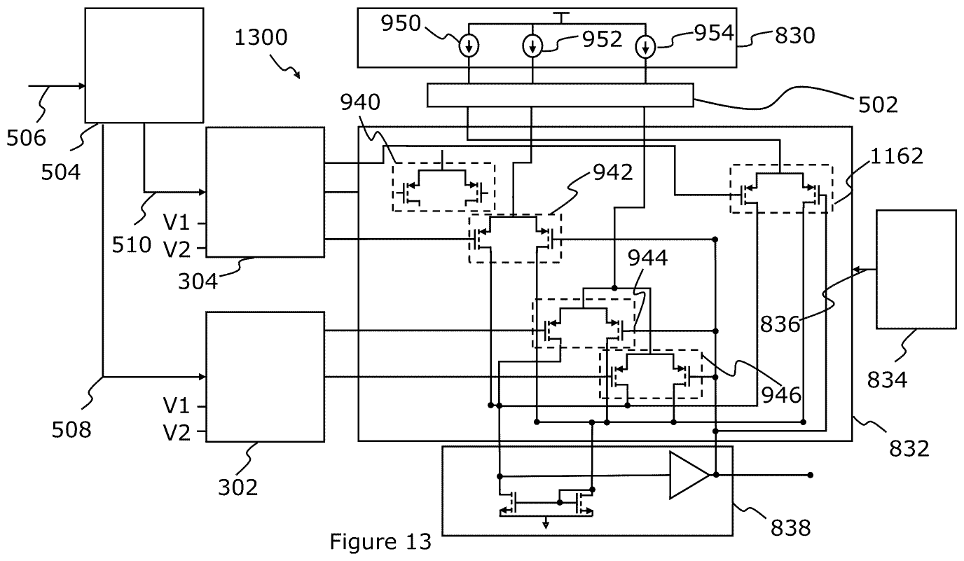

FIG. 13 is a schematic diagram of a DAC system 1300. The coupling of the first differential pair 940 and the redundant differential pair 1162 are modified compared to the coupling shown in FIG. 12. In particular, the first differential pair 940 has been disconnected or decoupled from the first MSB transconductance stage. The redundant differential pair 1162 has been coupled in place of the first differential pair 1162. As such, the subset of differential pairs of the first MSB transconductance stage is modified to include the redundant differential pair 1162 and not the first differential pair.

Notably, FIG. 13 shows the redundant differential pair 1162 being coupled to a different pin or terminal of the MSB section 304 compared to the pin or terminal that the first differential pair 940 was coupled to. This may be a permanent connection between the redundant differential pair 1162 and the MSB section 304. Further, all of the differential pairs of the plurality of differential pairs 832 may be coupled to different pins of the MSB 304 or LSB 302 sections respectively. As such, the MSB section 304 may be configured to supply different control signals to the respective pins of 304 in dependence on which differential pairs makeup the different subsets of differential pairs. In this way, the MSB section 304 controls which differential pairs makeup the different subsets by virtue of controlling the control signals supplied to the differential pairs. As such, no physical recoupling or reconnection of the differential pairs is required during operation.

FIG. 13 shows the first differential pair decoupled or disconnected from the MSB section, the plurality of current sources 830 and the output stage 838. This represents the first differential pair being redundant or not being used in the subsets of the MSB or LSB transconductance stages. It should be understood that the physical connections or conductors between the redundant differential pair and the MSB section 304, plurality of current sources 830 and output stage 838 may not be removed physically. Instead, when a differential pair is referred to as disconnected, decoupled or redundant, that may be achieved in a number of different ways. In particular, the current path between the plurality of current sources 830 and the output stage 838 through the redundant differential pair may be made inactive by virtue of:
Decoupling any current sources from the redundant differential pair using the switching circuit 502;
Providing an off signal to the gates of the redundant differential pair using the MSB section 304. This prevents current flowing through the differential pair;
Decoupling the output stage 838 from the redundant differential pair. This may be achieved by virtue of an output stage switching circuit (not shown in the figures) between the plurality of differential pairs 832 and the output stage 838. The output stage switching circuit may operate in a similar manner to the current source switching circuit 502, allowing control over the connection or disconnection of the output stage 838.

Notably, the above-described methods for deactivating the current path may be applied alone. For example, only the current sources may be decoupled. Alternatively, two or more of the methods for deactivating the current path may be applied in combination or at the same time. Using multiple methods to deactivate the current path may reduce the impact of off-state leakage.

Using the MSB 304 or LSB 302 section to deactivate a respective differential pair may be preferable, as it does not require a physical change in the operation of the circuit. Additionally, this is desirably achieved by digital functionality in the digital signal path.

As the redundant differential pair 1162 is included in one of the subsets of differential pairs, it may no longer be considered a redundant differential pair. Further, the first differential pair 940 that is no longer coupled as part of a subset may be considered a redundant differential pair.

As the redundant differential pair changes over time, the remapping circuit 1260 of the differential pair control circuit 834 may act to determine or monitor a property of the disconnected or redundant first differential pair 940. The properties of one or more of the differential pairs 832 may be determined by operating all or some of the differential pairs as a redundant device, determining a property of that differential pair, and then changing the coupling of the differential pairs such that a different pair is redundant. This allows the properties of all of the devices to be determined. Whilst an absolute property of the redundant differential pair 1162 may be determined, this may involve increased complexity. Relative properties between the differential pairs may be determined instead, for example a similarity and relative commonality or difference between the devices may be determined. In addition to determining the properties of redundant differential pairs, the remapping circuit 1260 may determine the properties of one or more of the differential pairs 832 whilst the DAC 1200 is not operating to provide an output. For example, the remapping circuit 1260 may determine the properties of all of the differential pairs 832 whilst the DAC 1200 is not operating to provide an output This may occur on startup of the DAC 1200.

FIGS. 8-13 show different DAC circuits in which the differential pairs that make up the transconductance stages are coupled in different manners. The differential pairs that make up the different subsets and thus act to provide the output of the DAC may be modified during a manufacturing process, periodically during DAC operation, in the background during DAC operation, continuously during DAC operation or on startup of the DAC. The differential pair control circuit 834 may determine which differential pairs are included in each respective subset of the MSB and LSB transconductance stages and their coupling. The different subsets of differential pairs may be determined in any suitable manner. This may occur during data changes, such as during circuit transitions.

The differential pairs that are included in each of the subsets may be determined using a dynamic element matching (DEM) operation. Dynamic element matching may rearrange the differential pairs that are included within each subset of the DAC to reduce the effects of mismatches among the differential pairs and other components of the DAC. Without dynamic element matching, the output of the DAC may comprise harmonic components at certain frequencies. These may be difficult to remove in post processing. By dynamically modifying the coupling of the differential pairs 832, the harmonic components in the output may be removed or reduced, such that the output includes noise across a wide frequency spectrum without significant peak harmonics. DEM modulates mismatch-noise to higher frequency, desirably outside of the signal bandwidth where this noise may be easier to remove, easier to filter at a system level and/or be outside the bandwidth of interest entirely such that no filtering is required.

In a dynamic element matching operation, the differential pair control circuit 834 or the remapping circuit 1260 of the differential pair control circuit 834, may be configured to sequence the usage of the DAC elements between the plurality of differential pairs 832 and select the respective subsets of the plurality of differential pairs 832 such that dynamic use of the DAC reduces the impact of the mismatch. Dynamic element matching involves sequencing the plurality of DAC elements as part of the different subsets in a sequential pattern such that the mismatch is averaged out over time. This results in the mismatch between the devices being modulated or noise shaped across a wide frequency spectrum at a high frequency. A DAC typically has a signal bandwidth below the update clock rate of the DAC, and the mismatch is modulated to a higher frequency such that it is above or outside of the signal bandwidth of the DAC. As such, the modulated noise has an, ideally, negligible impact on the signal performance in-band.

The differential pair control circuit 834 may be configured to modify the subsets periodically or continuously during DAC operation, such as between samples of the DAC. In particular, the configuration of the subsets of differential pairs may change and be chosen or selected dynamically to achieve noise-shaping of the mismatch.

In addition, or alternatively, the differential pairs that are included in each of the subsets may be determined such that the subsets do not comprise differential pairs of the plurality of differential pairs 832 that have outlier properties with respect to the remaining differential pairs. Outlier properties may relate to differential pairs with one or more properties that are substantially different from the properties of the remaining differential pairs. Determining whether a differential pair is an outlier may comprise comparing the differential pair to one or more threshold values or fitting the properties of the differential pairs to a distribution. The devices in the centre of the distribution may be used, and those that are a number of deviations away from the centre devices may be kept as redundant devices only. Considering a distribution of the devices or differential pairs is a relative comparison between the devices. This means that absolute values or properties of the devices do not need to be determined, but instead the devices with the greatest relative mismatch may not be included in the transconductance stages of the DAC. The inclusion of one or more redundant devices may allow significantly improved accuracy in this situation, and improve yield, as fewer DAC systems have to be discarded. The property of the differential pairs that is determined by the remapping circuit 1260 may be any property relevant to a DAC system, such as an on resistance of the devices, a linearity, a width to length ratio, amongst others.

Determining which differential pairs are part of the respective subsets may comprise determining which differential pairs have the most similar calibration result and using those that are the most similar. In particular, differential pairs that are unusual may be avoided, including those devices which have a property indicating a higher probability of future device failure.

The differential pairs that are included in each of the subsets may be determined using an ordered element matching (OEM) operation.

The differential pairs that are included in each of the subsets may be determined using a machine learning model. Machine learning (ML) models that are trained on a data set including a large number of differential pairs with different properties, may be used to identify a suggested solution, limited by measurement resolution, accuracy and precision. The final chosen subset may not be the exactly optimal subset, as models have finite capability. However, the use of a machine learning model may improve accuracy significantly and achieve the required accuracy of the DAC and/or increase manufacturability and yield.

The coupling of the plurality of current sources 830 may be modified in a similar manner to the modification of the differential pairs. Whilst the preceding description refers to changing the coupling of the current sources in dependence on a change in the input of the DAC by a particular value, it should be understood that the current source coupling may also be modified based on a number of alternative reasons.

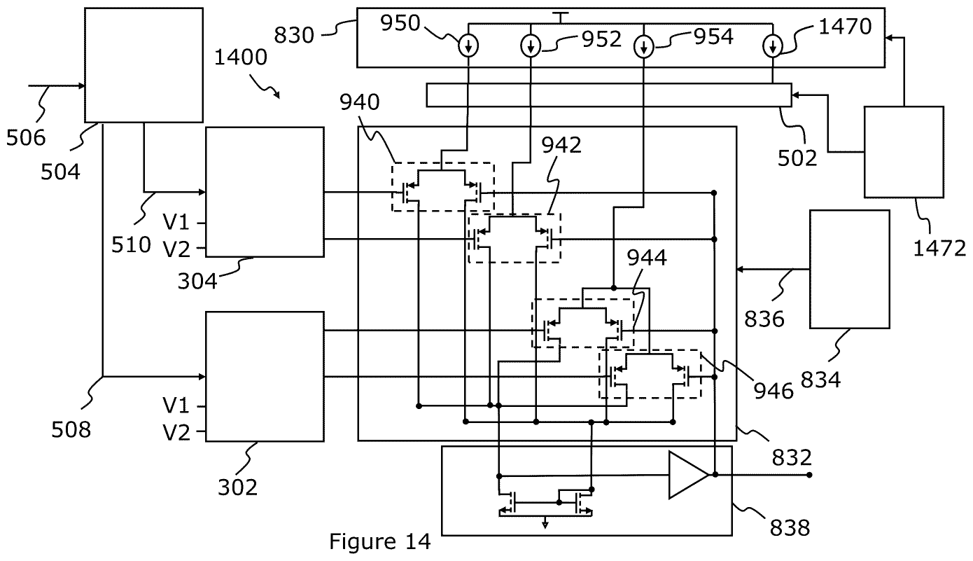

FIG. 14 is a schematic diagram of a DAC 1400. The plurality of current sources 830 include a first current source 950, a second current source 952, a third current source 954 and a calibration current source 1470. The calibration current source may also be referred to as a redundant current source. A current source calibration circuit 1472 is coupled to the plurality of current sources 830 and configured to calibrate the currents sources. Calibration circuit 1472 may also be referred to as a remapping circuit, as it acts to change, modify or remap the coupling of the current sources 830 and the remaining devices of the DAC 1400.

The plurality of current sources 830 may be configurable current sources, such that the current sourced or sank by each of the current sources may be modified. This is particularly useful where current source accuracy is important. As described throughout the preceding description, modifying the DAC input such that there is a switch in the output being provided by the LSB transconductance stage to the output being provided by one or more of the MSB transconductance stages may result in an error caused by a difference between the current sources.

The calibration current source 1470 may be a high accuracy current source compared to the remainder of the plurality of current sources 830. As such, the current source calibration circuit 1472 may calibrate the first current source 950, second current source 952 and third current source 954 against or with reference to the calibration current source 1470. Preferably, the current sources 830 may be identical or substantially identical current sources, such as unary current sources. Calibrating the current sources in the described manner allows improved correspondence between the current sources.

As well as modifying the connections of the current sources as the input to the DAC changes, the current source coupling or properties may also be changed to reduce any differences or errors between the current sources periodically, at start up or during a foreground or background calibration operation.

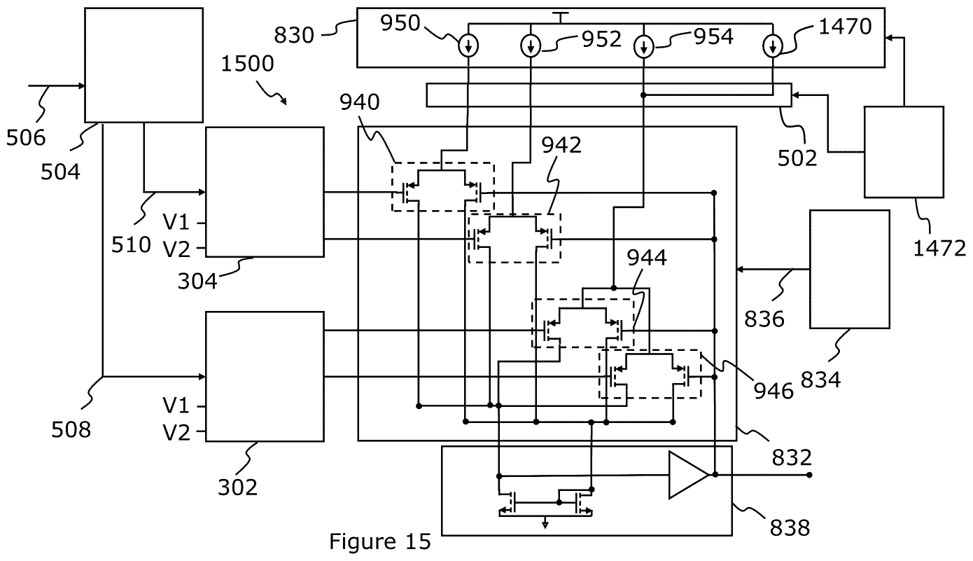

The current source calibration circuit 1472 may couple calibration current source 1470 in parallel with one or more of the plurality of current sources 830. FIG. 15 is a schematic diagram showing the calibration current source 1470 coupled in parallel with the third current source 954. This may allow the current provided by the parallel combination of the calibration current source 1470 and the third current source 954 to be modified. Where the calibration current source is a configurable current source, this may allow minor modifications in the combined output current, allowing a difference between the current sources to be reduced or removed.

The current source calibration circuit 1472 may determine one or more properties of the plurality of current sources 830, such as a current provided by the current sources. The current source calibration circuit 1472 may then be configured to control the coupling of the current sources 830 to the transconductance stages provided by the differential pairs 832 using the switching circuit 502 such that a mismatch between current sources, such as between the first current source 950 and the second current source 952, is minimised. The calibration process may ensure that post-calibration drift is minimised with respect to temperature, stress, parametric drift, mismatch drift and layout dependent effects.

The current source calibration circuit 1472 may modify the coupling of the current sources to the transconductance stages provided by the differential pairs 832 using the switching circuit 502 using calibration, dynamic element matching, ordered element matching or a machine learning model. This may be in the same manner as described with respect to the control of the differential pairs 832.

The calibration current sources 1470 may also be referred to as a redundant current source 1470 and provide the same current as the remainder of the current sources of the plurality of current sources 830. A redundant current source may be any current source of the plurality of current sources 830 that is not being used as part of the DAC system, to provide a current to the transconductance stages, at a moment in time.

The redundant current sources may be current sources that are provided that are beyond the needs or not required for operation of the DAC. These may be additional devices that are provided during manufacture.

When the DAC is statically encoded, the redundant devices are provided such that the yield is increased during manufacture (as devices with high mismatch do not have to be used, but the DAC still has enough devices to operate). Once the DAC has been encoded, the devices that are not used may be redundant devices and may not change during operation of the DAC. This is because the redundant devices have performed their function with respect to providing increased yield and manufacturing robustness.

In a DEM system, the redundant or additional devices are desirable or useful to enable the scrambling of mismatch. These redundant devices are especially useful when the DAC is operating near full-scale and would otherwise have long cycles resulting in AC artefacts. A greater number of redundant devices is desirable to allow rotating usage of devices (and thus redundant devices), avoiding artefacts cause by lack of or low redundancy. The redundant devices may therefore change regularly, as the encoding of the DAC is changed regularly.

As such, the one or more current sources that are considered to be redundant may change as the coupling of the current sources 830 is changed by the switching circuit 502.

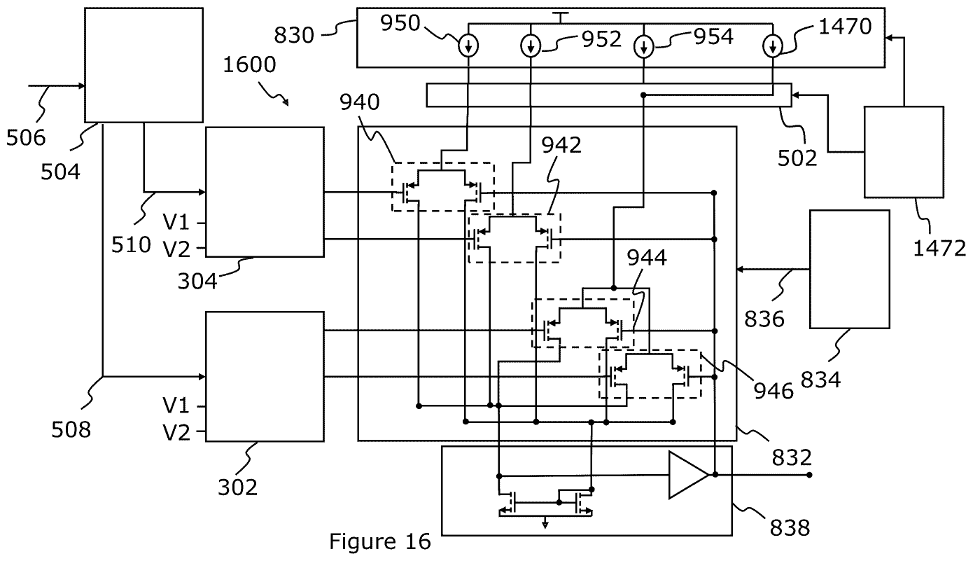

As shown in FIG. 14, the first current source 950 is coupled to the first differential pair 940. The second current source 952 is coupled to the second differential pair 942. The third current source 954 is coupled to the third differential pair 944 and the fourth differential pair 946. As shown in FIG. 16, the coupling of the current sources 830 may be modified, such that redundant current source 1470 is coupled to the third differential pair 944 and the fourth differential pair 946. The redundant current source therefore changes depending on the coupling of the devices. The current sources that are coupled to the differential pairs (and transconductance stages formed by the differential pairs) may be chosen in the same manner as described with respect to the differential pairs—such as to reduce a difference between the current sources. Whilst a redundant current source is not being used as part of the DAC system, it may be characterised by the current source calibration circuit 1472.

The current sources coupled to the DAC circuits may be unary current sources, such that they all provide substantially the same output current. As such, the transconductance stages may be referred to as unary transconductance stages or unary stages of the DAC. In addition to the unary stages, a binary (or substantially binary stage) may form part of the DAC.

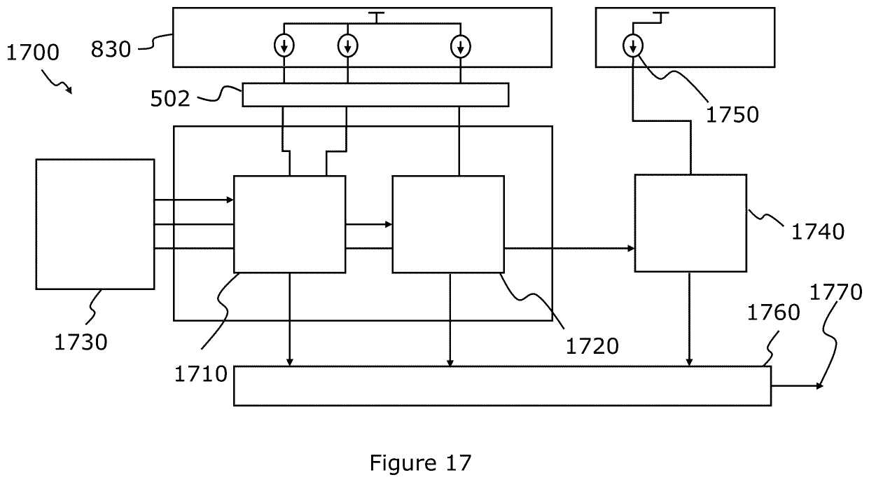

FIG. 17 is a schematic diagram of a DAC 1700 comprising two or more unary stages and a binary stage. The first unary stage 1710 may correspond to the one or more MSB transconductance stages described previously and the second unary stage 1720 may correspond to the LSB transconductance stage described previously. The unary stages are coupled to the plurality of currents sources 830 via the switching circuit 502. In addition to the unary stages, the DAC circuit 1600 comprises a binary stage 1740, which may also be referred to as a binary transconductance stage 1740. The binary transconductance stage is coupled to an additional current source 1750. The unary and binary stages are coupled to an output stage 1760 so as to provide an output 1770 of the DAC. The stages are controlled by control system 1730, which may provide multiple reference voltages to the stages in dependence on the input of the DAC. The control system 1730 may perform the function of the MSB 304 and LSB 302 sections as described previously, as well as control the binary stage 1740, providing reference values to each of the stages.

The additional current source 1750 may provide a different current when compared to the plurality of current sources 830. As such, the additional current source 1750 may be referred to as a binary current source and the plurality of currents sources 830 may be referred to as unary current sources.

To improve the accuracy of the relationship between the binary stage 1740 and the unary stages 1710, 1720, the additional current source 1750 may be a scaled replica of the plurality of current sources 830. The current sources may be constructed from replicated units. For example, the additional current source 1750 may be made from a unit of the plurality of current sources 830 for both nominal matching and tracking over temperature and stress.

Whilst the description herein refers to a binary stage 1740 and a binary current source 1750, it should be understood that these may be substantially or near binary stages, with values for example between 1-9-2.1, 1.8-2.2, 1.7-2.3, or other values or ranges near to binary. As such, the binary transconductance stage 1740 may be referred to as a non-unary transconductance stage or a substantially binary transconductance stage.

The differential input provided to the DAC 1700 comprises a first segment comprising X most significant bits, MSBs, and a second segment comprising Y least significant bits, LSBs. The one or more MSB transconductance stages 1710 are configured to provide an output in dependence on the X most significant bits. The LSB transconductance stage 1720 is configured to provide an output in dependence on a first portion of the Y least significant bits. The binary transconductance stage 1740 is configured to provide an output in dependence on a second portion of the Y least significant bits.

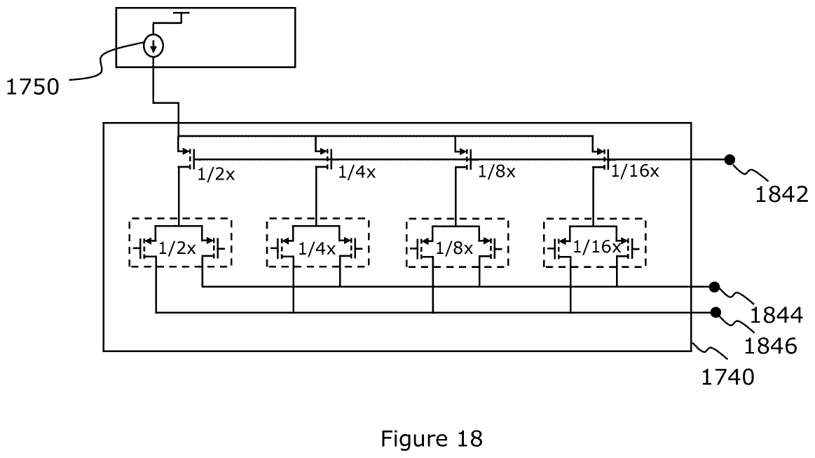

As described with respect to FIG. 7, each of the unary stages may comprise a degeneration transistor and a plurality of differential pairs. The binary stage may comprise a plurality of degeneration transistors of different width to length ratios coupled to a plurality of differential pairs of different width to length ratios. FIG. 18 shows one example of the binary transconductance stage. FIG. 18 represents a four-bit binary stage, comprising four differential pairs and four degeneration transistors.

The gates of the degeneration transistors are coupled to a gate biasing signal or terminal 1842. Notably, whilst the degeneration transistors are shown in the binary transconductance stage of FIG. 18, the binary transconductance stage may operate without the degeneration transistors, as described with respect to FIGS. 6a-6c. As such the degeneration transistors may not be present, with only the differential pairs included in the binary stage 1740. When present, the degeneration transistors of FIG. 18 may operate in the same manner as those described with respect to FIG. 7.

The binary stage 1740 comprises a first output 1844 and a second output 1846. The first and second outputs may be coupled to the output stage 1760, in the same manner that the outputs of the unary stages are coupled to the output stage 838 as described with respect to FIGS. 9-16.

The gates of the differential pairs of 1740 are coupled to the control system 1730, which provides multiple reference voltages to the differential pairs in dependence on the input of the DAC.

Each of the differential pairs and degeneration transistors have a different width to length ratio, allowing the output to be controlled in dependence on the input code by switching different ones of the differential pairs. The degeneration transistors may be optional, and the binary stage may comprise only the differential pairs. As such, each of the differential pairs is configured to represent a different binary value.

The differential pairs shown and described throughout the description may be MOSFET devices. However, it should be understood that any suitable switching element may be used. For example, any suitable field effect transistor (FET) may be used, whether they are oxide or non-oxide devices, such as poly-oxide silicon devices. Alternatively, JFETs, finFETs, gate all around (GAA) FETs, Hi-K and metal gate (HKMG) devices may be used. The current sources may be degenerated MOS devices or include JFETs instead of FET transistors.

The preceding description refers to a number of control systems, such as differential pair control circuit 834, a current source calibration circuit 1472 and MSB section 304, an LSB section 302, a control system 1730, 504. It should be understood that these have been depicted or represented as different circuits or systems, by may instead be represented by one or more combined systems, such as a single control system. Any suitable arrangement of the control systems may be provided.

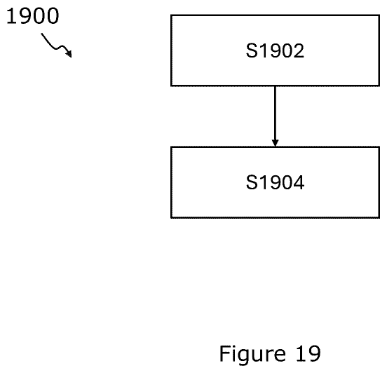

There may also be provided a method of controlling a DAC in accordance with the preceding figures comprising a plurality of differential pairs and a plurality of current sources. FIG. 19 shows a method 1900 of controlling the operation of the DAC. In a first step S1902, the method comprises controlling a configurable coupling of a plurality of differential pairs such that they form part of an LSB transconductance stage or an MSB transconductance stage. In a second step S1904, the method comprises controlling a configurable coupling between a plurality of current sources and the LSB transconductance stage and the MSB transconductance stage, such that the first current source is coupled to one of the LSB transconductance stage and the MSB transconductance stage, and the second current source is coupled to the other of the LSB transconductance stage and the MSB transconductance stage.

Steps S1902 and S1904 may occur concurrently or consecutively. Where they occur consecutively, they may occur in any order. The controlling of the coupling of the differential pairs and current sources may be in accordance with the previously described figures and occur using any suitable technique. Modifying the coupling of the elements may also be provided periodically during operation of the DAC, as described previously. Further, the control of the coupling of the current sources and differential pairs may occur at different times.

Whilst the system of the preceding figures has been referred to as a DAC, it should be understood that the system of FIGS. 8-17 may additionally or alternatively be referred to as an interpolating DAC, a DAC-embedded amplifier, an amplifier suitable for use within a DAC or a sub-section or stage of a DAC.

Where one or more of the MOS devices are described as being “off” or provided with an “off signal”, it should be understood that a residual MOS leakage current may be present. It will be appreciated that there are different types of residual MOS leakage current including sub-threshold (or sub-vth) current, drain-induced barrier lowering (DIBL) induced, gate-induced drain leakage (GIDL) and stress-induced Leakage current (SILC) which may be present. Any suitable technique may be applied to reduce the leakage current that is present. For example, Narendra, S. G. and Chandrakasan, “Leakage in nanometer CMOS technologies”, Springer Science & Business Media, 2006 describes a number of methods to reduce leakage current, and is incorporated by reference herein.

Various modifications whether by way of addition, deletion, or substitution of features may be made to the above-described examples to provide further examples, any and all of which are intended to be encompassed by the appended claims.

### ASPECTS OF THE INVENTION

Included below are a set of numbered aspects according to the disclosure:

1. A method for controlling a digital-to-analog converter, DAC, the method comprising:
receiving a digital input comprising a plurality of bits including a first segment comprising X most significant bits, MSBs, and a second segment comprising Y least significant bits, LSBs;
detecting a change in the value of the MSBs and detecting a change in the value of the LSBs by 2^{Y}-1;
decoupling a first current source from a least-significant bit, LSB, transconductance stage of the DAC; and
coupling the first current source to a first most-significant bit, MSB, transconductance stage of the DAC.

2. The method according to aspect 1, further comprising:
decoupling a second current source from the first MSB transconductance stage of the DAC;
coupling the second current source to a second MSB transconductance stage of the DAC.

3. The method according to aspect 1 or aspect 2, further comprising:
decoupling a third current source from the second MSB transconductance stage of the DAC; and
coupling the third current source to the LSB transconductance stage of the DAC.

4. The method according to aspect 1, further comprising:
decoupling a second current source from the first MSB transconductance stage of the DAC;
coupling the second current source to the LSB transconductance stage of the DAC.

5. The method according to any preceding aspect, wherein detecting a change in the value of the MSBs and a change in the value of the LSBs by 2^{Y}-1 comprises:
detecting an increase in the value of the MSBs by 2^{Y} or more and a change in the value of the LSBs from 2^{Y}-1 to 0.

6. The method according to any of aspects 1-4, wherein detecting a change in the value of the MSBs and a change in the value of the LSBs by 2^{Y} comprises:
detecting a decrease in the value of the MSBs by 2^{Y} or more and a change in the value of the LSBs from 0 to 2^{Y}-1.

7. The method according to any preceding aspect, further comprising:
converting, using the LSB transconductance stage, the Y LSBs to a first analog signal;
converting, using the MSB transconductance stages, the X MSBs to a second analog signal.

8. The method according to aspect 7, further comprising:
combining the first analog signal and the second analog signal to provide an analog output signal.

9. The method according to aspect 7 or aspect 8, wherein:
the LSB transconductance stage comprises one or more differential pairs, and wherein converting, using the LSB transconductance stage, the Y LSBs to a first analog signal comprises modifying one or more control signals supplied to the one or more differential pairs of the LSB transconductance stage;
the MSB transconductance stages comprise each comprise a differential pair, and wherein converting, using the MSB transconductance stages, the X MSBs to a second analog signal comprises modifying one or more control signals supplied to differential pairs of the MSB transconductance stages.

10. A digital-to-analog converter, DAC, circuit comprising:
an input for receiving a digital input comprising a plurality of bits including a first segment comprising X most significant bits, MSBs, and a second segment comprising Y least significant bits, LSBs;
an LSB transconductance stage;
one or more MSB transconductance stages comprising a first transconductance stage;
a first current source;
a switching circuit, the switching circuit coupled between the first current source and the LSB transconductance stage and the one or more MSB transconductance stages, wherein, when the value of the MSBs change and the value of the LSBs change by 2^{Y}-1, the switching circuit is configured to:
decouple the first current source from the LSB transconductance stage and couple the first current source to the first MSB transconductance stage.

11. The DAC circuit according to aspect 10, further comprising
a second current source;
wherein the one or more MSB transconductance stages comprise a second MSB transconductance stage, and
wherein the switching circuit is coupled between the second current source, the LSB transconductance stage and the one or more MSB transconductance stages, wherein, when the value of the MSBs change and the value of the LSBs change by 2^{Y}-1, the switching circuit is configured to:
decouple the second current source from the first MSB transconductance stage and couple the second current source to the second MSB transconductance stage.

12. The DAC circuit according to aspect 10 or aspect 11, further comprising
a third current source;
wherein the switching circuit is coupled between the third current source, the LSB transconductance stage and the one or more MSB transconductance stages, wherein, when the value of the MSBs change and the value of the LSBs change by 2^{Y}-1, the switching circuit is configured to:
decouple the third current source from the second MSB transconductance stage and couple the second current source to the LSB transconductance stage.

13. The DAC circuit according to aspect 10, further comprising
a second current source;
wherein the one or more MSB transconductance stages comprise a second MSB transconductance stage, and
wherein the switching circuit is coupled between the second current source, the LSB transconductance stage and the one or more MSB transconductance stages, wherein, when the value of the MSBs change and the value of the LSBs change by 2^{Y}-1, the switching circuit is configured to:
decouple the second current source from the first MSB transconductance stage and couple the second current source to the LSB transconductance stage of the DAC.

14. The DAC circuit according to any of aspects 10-13, wherein the LSB transconductance stage comprises:
2^{Y} LSB differential pairs, each LSB differential pair comprising a first transistor and a second transistor,
wherein a source of the first transistor and a source of the second transistor of the LSB differential pairs are coupled to each other and to the switching circuit.

15. The DAC circuit according to any of aspects 10-13, wherein the LSB transconductance stage comprises:
2^{Y}-1 LSB differential pairs, each LSB differential pair comprising a first transistor and a second transistor,
wherein a source of the first transistor and a source of the second transistor of the LSB differential pairs are coupled to each other and to the switching circuit.

16. The DAC circuit according to any of aspects 14 or 15, wherein each of the one or more MSB transconductance stages comprises:
an MSB differential pair, the MSB differential pair having a width-to-length ratio that is 2^{Y} times greater than a width-to-length of the LSB differential pairs.

17. The DAC circuit according to any of aspects 14-16, wherein the LSB transconductance stage further comprises:
a degeneration transistor biased in the linear region, the degeneration transistor coupled between the switching circuit and the sources of the LSB differential pairs, wherein the degeneration transistor has a width to length ratio that is less than a width to length ratio of the LSB differential pairs.

18. The DAC circuit according to any of aspect 14-16, wherein the LSB transconductance stage further comprises:
a plurality of cascode transistors, each cascode transistor coupled between the switching circuit and the sources of a respective differential pair of the LSB differential pairs.

19. A method for controlling a digital-to-analog converter, DAC, the method comprising:
receiving a digital input;
detecting a change in the value of the most significant bits, MSBs, of the digital input and detecting a change in the value of the least significant bits, LSBs, of the digital input by 2^{Y}-1;
decoupling a first current source from a first transconductance stage of the DAC; and
coupling the first current source to a second transconductance stage of the decoder.

20. The method according to aspect 19, further comprising:
decoupling a second current source from the second transconductance stage of the decoder;
coupling the second current source to a third transconductance stage of the decoder.

A second set of numbered aspects are included below:

1. A digital-to-analog converter, DAC, circuit comprising:
an input for receiving a digital input comprising a plurality of bits;
an LSB transconductance stage;
an MSB transconductance stage;
a plurality of current sources, the plurality of current sources comprising a first current source and a second current source; and
a switching circuit, the switching circuit configurable to modify a coupling between the plurality of current sources and the LSB transconductance stage and the MSB transconductance stage, wherein the switching circuit is configured to:
couple the first current source to one of the LSB transconductance stage and the MSB transconductance stage, and couple the second current source to the other of the LSB transconductance stage and the MSB transconductance stage.

2. The DAC circuit according to aspect 1, further comprising a plurality of differential pairs and a differential pair control circuit.

3. The DAC circuit according to aspect 2, wherein the differential pair control circuit is configured to control a configurable coupling of each of the plurality of differential pairs such that they form part of the LSB transconductance stage or the MSB transconductance stage.

4. The DAC circuit according to aspect 2 or aspect 3, wherein the differential pair control circuit is configured to control the configurable coupling of each of the plurality of differential pairs such that each of the LSB transconductance stage and the MSB transconductance stage comprises respective subsets of the plurality of differential pairs, the respective subsets of the plurality of differential pairs coupled to the plurality of current sources.

5. The DAC circuit according to aspect 4, wherein the differential pair control circuit is configured to modify the respective subsets of the plurality of differential pairs to comprise different differential pairs of the plurality of differential pairs.

6. The DAC circuit according to aspect 4 or aspect 5, wherein the plurality of differential pairs comprise one or more redundant differential pairs that do not form part of the respective subsets.

7. The DAC circuit according to any of aspects 4-6, wherein each of the respective subsets of the plurality of differential pairs are selected using dynamic element matching.

8. The DAC circuit according to aspect 7, wherein the differential pair control circuit is configured to determine a mismatch between the plurality of differential pairs and select the respective subsets of the plurality of differential pairs such that dynamic use of the DAC reduces the impact of the mismatch.

9. The DAC circuit according to aspect 6, wherein modifying the respective subsets comprises including one or more of the redundant differential pairs in the respective subsets of the plurality of differential pairs.

10. The DAC circuit according to aspect 6 or aspect 9, further comprising a calibration circuit, the calibration circuit configured to determine a property of the one or more redundant differential pairs.

11. The DAC circuit according to aspect 10, wherein the calibration circuit is configured to determine the property of the one or more redundant differential pairs whilst the DAC circuit is operating to provide an analog output.

12. The DAC according to aspect 10 or 11, wherein each of the respective subsets are modified such that the subsets do not comprise differential pairs of the plurality of differential pairs that have outlier properties with respect to the remaining differential pairs.

13. The DAC according to any of aspects 4-12, wherein each of the respective subsets of the plurality of differential pairs are selected using ordered element matching.

14. The DAC circuit according to any of aspects 4-12, wherein each of the respective subsets of the plurality of differential pairs are selected using a machine learning model.

15. The DAC circuit according to any of aspects 5-14, wherein the differential pair control circuit is configured to modify the respective subsets of differential pairs in accordance with at least one of the following:
during a manufacturing process of the DAC circuit;
whilst the DAC circuit is not being used to provide an output;
in the background whilst the DAC circuit is being used to provide the output.

16. The DAC circuit according to any preceding aspect, wherein the plurality of current sources comprise a calibration current source.

17. The DAC circuit according to any preceding aspect, further comprising a current source calibration circuit configured to calibrate the first current source and the second current source with reference to the calibration current source.

18. The DAC circuit according to aspect 15 or aspect 16, wherein the switching circuit is configured to couple the calibration current source in parallel with the first current source or the second current source to reduce a mismatch of the first current source or the second current source.

19. The DAC circuit according to any preceding aspect, wherein the switching circuit is configurable to select the first current source and the second source from the plurality of current sources such that a mismatch between the first current source and the second current source is minimised.

20. The DAC circuit according to any preceding aspect, wherein the switching circuit is configurable to select the coupling between the plurality of current sources and the LSB transconductance stage and the MSB transconductance stage using dynamic element matching.

21. The DAC circuit according to any preceding aspect, wherein the switching circuit is configurable to select the coupling between the plurality of current sources and the LSB transconductance stage and the MSB transconductance stage using ordered element matching.

22. The DAC circuit according to any preceding aspect, wherein the switching circuit is configurable to select the coupling between the plurality of current sources and the LSB transconductance stage and the MSB transconductance stage using a machine learning model.

23. The DAC circuit according to any preceding aspect, wherein the plurality of current sources are configured to provide substantially the same current.

24. The DAC circuit according to any preceding aspect, further comprising an additional current source.

25. The DAC circuit according to aspect 23 or aspect 24, wherein the MSB transconductance stage and the LSB transconductance stages are unary transconductance stages.

26. The DAC circuit according to aspect 25, further comprising a binary transconductance stage.

27. The DAC circuit according to aspect 26, wherein the binary transconductance stage comprises a second plurality of differential pairs.

28. The DAC circuit according to aspect 27, wherein the second plurality of differential pairs are coupled to the additional current source.

29. The DAC circuit according to aspect 28, wherein each of the second plurality of differential pairs is configured to represent a different binary value.

30. The DAC circuit according to any of aspects 24-29, wherein the additional current source is a scaled replica of one of the plurality of current sources.

31. The DAC circuit according to aspect 25, further comprising a non-unary transconductance stage.

32. The DAC circuit according to any of aspect 25-30, wherein the digital input comprises a first segment comprising X most significant bits, MSBs, and a second segment comprising Y least significant bits, LSBs.

33. The DAC circuit according to aspect 32, wherein:
the one or more MSB transconductance stages are configured to provide an output in dependence on the X most significant bits;
the LSB transconductance stage is configured to provide an output in dependence on a first portion of the Y least significant bits;
the binary transconductance stage is configured to provide an output in dependence on a second portion of the Y least significant bits.

35. The DAC circuit according to aspect 2, further comprising a remapping system configured to modify a coupling between the plurality of current sources and the plurality of differential pairs.

36. A digital-to-analog converter, DAC, circuit comprising:
an input for receiving a digital input comprising a plurality of bits;
a plurality of differential pairs;
a differential pair control circuit is configured to control a configurable coupling of each of the plurality of differential pairs such that they form part of an LSB transconductance stage or an MSB transconductance stage;
a plurality of current sources, the plurality of current sources comprising a first current source and a second current source; and
a switching circuit, the switching circuit configurable to modify a coupling between the plurality of current sources and the LSB transconductance stage and the MSB transconductance stage, wherein the switching circuit is configured to couple the first current source to one of the LSB transconductance stage and the MSB transconductance stage, and couple the second current source to the other of the LSB transconductance stage and the MSB transconductance stage.

37. A digital-to-analog converter, DAC, circuit comprising:
an input for receiving a digital input comprising a plurality of bits;
an LSB unary transconductance stage;
an MSB unary transconductance stage;
a plurality of unary current sources, the plurality of unary current sources comprising a first unary current source and a second unary current source;
a switching circuit, the switching circuit configurable to modify a coupling between the plurality of current sources and the LSB transconductance stage and the MSB transconductance stage, wherein the switching circuit is configured to couple the first current source to one of the LSB transconductance stage and the MSB transconductance stage, and couple the second current source to the other of the LSB transconductance stage and the MSB transconductance stage;
a non-unary transconductance stage; and
an additional current source, the additional current source coupled to the non-unary transconductance stage.

38. A method for controlling a digital-to-analog converter, DAC, comprising a plurality of differential pairs and a plurality of current sources, the method comprising:
controlling a configurable coupling of a plurality of differential pairs such that they form part of an LSB transconductance stage or an MSB transconductance stage;
controlling a configurable coupling between a plurality of current sources and the LSB transconductance stage and the MSB transconductance stage, such that the first current source is coupled to one of the LSB transconductance stage and the MSB transconductance stage, and the second current source is coupled to the other of the LSB transconductance stage and the MSB transconductance stage.

1. A digital-to-analog converter (DAC) circuit comprising:
an input for receiving a digital input comprising a plurality of bits;
a least significant bit (LSB) transconductance stage;
a most significant bit (MSB) transconductance stage;
a plurality of current sources, the plurality of current sources comprising a first current source and a second current source; and
a switching circuit, the switching circuit configurable to modify a coupling between the plurality of current sources and the LSB transconductance stage and the MSB transconductance stage, wherein the switching circuit is configured to:
couple the first current source to one of the LSB transconductance stage and the MSB transconductance stage, and couple the second current source to the other of the LSB transconductance stage and the MSB transconductance stage.

2. The DAC circuit according to claim 1, further comprising a plurality of differential pairs and a differential pair control circuit, wherein the differential pair control circuit is configured to control a configurable coupling of each of the plurality of differential pairs such that the plurality of differential pairs form part of the LSB transconductance stage or the MSB transconductance stage.

3. The DAC circuit according to claim 2, wherein the differential pair control circuit is configured to control the configurable coupling of each of the plurality of differential pairs such that each of the LSB transconductance stage and the MSB transconductance stage comprises respective subsets of the plurality of differential pairs, the respective subsets of the plurality of differential pairs coupled to the plurality of current sources.

4. The DAC circuit according to claim 3, wherein the differential pair control circuit is configured to modify the respective subsets of the plurality of differential pairs to comprise different differential pairs of the plurality of differential pairs.

5. The DAC circuit according to claim 3, wherein the plurality of differential pairs comprise one or more redundant differential pairs that do not form part of the respective subsets.

6. The DAC circuit according to claim 5, further comprising a calibration circuit, the calibration circuit configured to determine a property of the one or more redundant differential pairs.

7. The DAC according to claim 6, wherein each of the respective subsets are modified such that the subsets do not comprise differential pairs of the plurality of differential pairs that have outlier properties with respect to the remaining differential pairs.

8. The DAC circuit according to claim 3, wherein each of the respective subsets of the plurality of differential pairs are selected using dynamic element matching.

9. The DAC circuit according to claim 8, wherein the differential pair control circuit is configured to determine a mismatch between the plurality of differential pairs and select the respective subsets of the plurality of differential pairs such that dynamic use of the DAC reduces an impact of the mismatch.

10. The DAC according to claim 3, wherein each of the respective subsets of the plurality of differential pairs are selected using ordered element matching.

11. The DAC circuit according to claim 1, wherein the plurality of current sources comprise a calibration current source and a current source calibration circuit configured to calibrate the first current source and the second current source with reference to the calibration current source.

12. The DAC circuit according to claim 11, wherein the switching circuit is configured to couple the calibration current source in parallel with the first current source or the second current source to reduce a mismatch of the first current source or the second current source.

13. The DAC circuit according to claim 1, wherein the switching circuit is configurable to select the first current source and the second current source from the plurality of current sources such that a mismatch between the first current source and the second current source is minimised.

14. The DAC circuit according to claim 1, wherein the switching circuit is configurable to select the coupling between the plurality of current sources and the LSB transconductance stage and the MSB transconductance stage using dynamic element matching.

15. The DAC circuit according to claim 1, further comprising an additional current source.

16. The DAC circuit according to claim 15, wherein the MSB transconductance stage and the LSB transconductance stages are unary transconductance stages, and wherein the DAC circuit further comprises a binary transconductance stage.

17. The DAC circuit according to claim 16, wherein the binary transconductance stage comprises a second plurality of differential pairs coupled to the additional current source.

18. The DAC circuit according to claim 17, wherein each of the second plurality of differential pairs is configured to represent a different binary value.

19. A digital-to-analog converter (DAC) circuit comprising:
an input for receiving a digital input comprising a plurality of bits;
an LSB unary transconductance stage;
an MSB unary transconductance stage;
a plurality of unary current sources, the plurality of unary current sources comprising a first unary current source and a second unary current source;
a switching circuit, the switching circuit configurable to modify a coupling between the plurality of unary current sources and the LSB unary transconductance stage and the MSB unary transconductance stage, wherein the switching circuit is configured to couple the first unary current source to one of the LSB unary transconductance stage and the MSB unary transconductance stage, and couple the second unary current source to the other of the LSB unary transconductance stage and the MSB unary transconductance stage;
a non-unary transconductance stage; and
an additional non-unary current source, the additional non-unary current source coupled to the non-unary transconductance stage.

20. A method for controlling a digital-to-analog converter (DAC) comprising a plurality of differential pairs and a plurality of current sources, the plurality of current sources comprising a first current source and a second current source, the method comprising:
controlling a configurable coupling of a plurality of differential pairs such that the plurality of differential pairs form part of an LSB transconductance stage or an MSB transconductance stage;
controlling a configurable coupling between a plurality of current sources and the LSB transconductance stage and the MSB transconductance stage, such that the first current source is coupled to one of the LSB transconductance stage and the MSB transconductance stage, and the second current source is coupled to the other of the LSB transconductance stage and the MSB transconductance stage.
